(19) United States
(12) Patent Application Publication
(10) Pub. No.: US 2009/0218676 A1
(43) Pub. Date: Sep. 3, 2009

(54) SEMICONDUCTOR DEVICE

(75) Inventors: Kuniharu MUTO, Tokyo (JP); Tadatoshi DANNO, Tokyo (JP); Hiroyuki TAKAHASHI, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/393,031

(22) Filed: Feb. 25, 2009

(30) Foreign Application Priority Data
Feb. 29, 2008 (JP) 2008-049628
Dec. 26, 2008 (JP) 2008-332756

(51) Int. Cl. H01L 23/48

(52) U.S. Cl. 257/693; 257/E23.01

(57) ABSTRACT

A small-sized surface mount package having a low on-resistance is achieved, in which a power MOSFET etc. is sealed. In one side a molding resin, two silicon chips are sealed. On one side of the molding resin, three source leads and one gate lead are arranged. The three source leads are joined each other inside the molding resin, and the joined portion and a source pad of the silicon chip are electrically coupled each other via two Al ribbons. Moreover, a gate pad of the silicon chip is electrically coupled to the gate lead via one Au wire.

### CROSS-REFERENCE TO RELATED APPLICATION

The disclosure of Japanese Patent Application No. 2008-332756 filed on Dec. 26, 2008 and the disclosure of Japanese Patent Application No. 2008-49628 filed on Feb. 29, 2008 including the specification, drawings and abstract are incorporated herein by reference in its entirety.

### BACKGROUND OF THE INVENTION

The present invention relates to a semiconductor device, especially, it relates to a technology which is useful for a semiconductor device including a small-sized surface mount package.

A power MOSFET (Metal Oxide Semiconductor Field Effect Transistor) which is used for the power control switch and the charge/discharge protection circuit switch etc. of a portable information apparatus, is sealed in a small-sized surface mount package such as a SOP8. Such a kind of power MOSFET is described in, for example, Patent Document 1 (Japanese patent laid-open No. 2000-164869) and Patent Document 2 (Japanese patent laid-open No. 2000-299464).

Patent Document 1 discloses a technology which reduces risk of occurrence of punch-through breakdown in a trench-gate power MOSFET (Metal Oxide Semiconductor Field Effect Transistor) formed in a structure including a p-type epitaxial layer that forms the upper layer of an n⁺-type silicon substrate, by forming an n-type drain region so as to extend between the n⁺-type silicon substrate and the bottom of a trench, and forming a joined portion between the n-type drain region and the p-type epitaxial layer so as to extend between the n⁺-type silicon substrate and a bulkhead of the trench.

Moreover, Patent Document 2 discloses a technology, which reduces the on-resistance of the drain region, by providing a first conductive type epitaxial layer and a second conductive type well layer over a first conductive type semiconductor substrate, providing a deep trench gate isolated by an insulating layer inside an upper layer composed of the epitaxial layer and the well layer, providing a drain region under the trench gate, providing a source region neighboring to the trench gate, and providing a bulk region doped with impurities having a higher concentration than that of the well layer in the upper portion of the well layer.

### SUMMARY OF THE INVENTION

The present inventor has been considered with regard to a small-sized surface mount package such as a SOP8 for sealing a silicon chip in which a power MOSFET is formed.

The SOP8 for which the present inventor investigated, is a surface mount type package in which a silicon chip is sealed with an epoxy-based molding resin, and the silicon chip is mounted over a die pad portion that is integrally formed with a drain lead, with its main surface upward. The rear surface of the silicon chip constitutes the drain of a power MOSFET, and it is joined to the top surface of die pad portion via an Ag paste.

On the main surface of the silicon chip, a source pad and a gate pad are formed. The source pad and the gate pads are constituted with a conductive film mainly composed of an Al-film formed in the uppermost layer of the silicon chip. In order to reduce the on-resistance of the power MOSFET, the source pad is constituted so as to have an area larger than that of the gate pad. By a similar reason, the entire rear surface of the silicon chip constitutes the drain of the power MOSFET.

Outside a molding resin, a source lead, a drain lead, and a gate lead are exposed, which constitute the external connection terminals of the SOP8. The source lead and the source pad, and the gate lead and the gate pad, are electrically coupled by Au wires, respectively. The gate pad, since its area is small, is electrically coupled to the gate lead by one Au wire. On the other hand, the source pad, since its area is larger than that of the gate pad, is electrically coupled to the source lead by a plurality of Au wires.

However, it is difficult for a SOP8 having a construction as mentioned above to reduce the on-resistance of a power MOSFET, thereby resulting in limitation for improving the performance of a device. This is because, since the contact area between the source pad or the source lead and the Au wire is small, even if the number of the Au wires is increased, it is difficult to ensure a sufficient contact area.

An object of the present invention is to achieve a surface mount package capable of reducing the on-resistance of a power MOSFET.

Another object of the present invention is to achieve a high performance surface mount package including a power MOSFET.

Still another object of the present invention is to improve the reliability and manufacturing yield of a surface mount package including a power MOSFET.

The above and further objects and novel features of the present invention will more fully appear from the following detailed description in this specification and the accompanying drawings.

Preferred embodiments of the present invention which will be described herein are briefly outlined beneath.

(1) A semiconductor device that is an invention of the present application is the one in which a first semiconductor chip mounted over a first die pad portion and a second semiconductor chip mounted over a second die pad portion are sealed in a resin package, and outer lead portions of a plurality of leads are exposed from a side surface of the resin package; wherein on a main surface of each of the first and second semiconductor chips, there are formed a power MOSFET, a gate pad coupled to a gate electrode of the power MOSFET, and a source pad coupled to a source of the power MOSFET and having an area larger than that of the gate pad; wherein on a rear surface of each of the first and second semiconductor chips, a drain electrode of the power MOSFET is formed; wherein between the rear surface of the first semiconductor chip and the first die pad portion, and between the rear surface of the second semiconductor chip and the second die pad portion, Ag pastes are intervened, respectively; wherein the leads include a first gate lead electrically coupled to the gate pad of first semiconductor chip, a first source lead electrically coupled to the source pad of first semiconductor chip, a second gate lead electrically coupled to the gate pad of second semiconductor chip, and a second source lead electrically coupled to the source pad of second semiconductor chip; and wherein at least the source pad of first semiconductor chip and the first source lead are electrically coupled each other by a metal ribbon.

(2) A semiconductor device that is another invention of the present application is the one in which a semiconductor chip mounted on a die pad portion is sealed in a resin package, and outer lead portions of a plurality of leads are exposed from a side surface of the resin package; wherein on a main surface of the semiconductor chip, there are formed a power MOSFET, a gate pad coupled to a gate electrode of the power MOSFET, and a plurality of source pads coupled to a source of the power MOSFET and having an area larger than that of the gate pad; wherein on a rear surface of the semiconductor chip, a drain electrode of the power MOSFET is formed; wherein between the rear surface of semiconductor chip and the die pad portion, an Ag paste is intervened; wherein the leads include a gate lead electrically coupled to the gate pad of semiconductor chip and a source lead electrically coupled to the source pad of semiconductor chip; wherein, each of the source pads and the source lead are electrically coupled each other by a metal ribbon; and wherein, the gate pad is arranged among the source pads.

In the present invention, an Al ribbon means a stripe-shaped wire connection material mainly composed of a conductive material containing Al as a principal component. Usually, the Al ribbon is provided to a bonding apparatus in a state wound around a spool. Methods for coupling the Al ribbon to a lead or a pad include ultrasonic bonding and laser bonding. Since the Al ribbon is extremely thin, when coupling it to a lead and a pad, the length and the loop shape thereof can be set arbitrarily.

Moreover, as a wire connection material similar to the Al ribbon, there is a material called a clip. This is the one obtained by forming a thin metal plate composed of a Cu alloy or Al etc. preliminarily into a predetermined loop shape and a predetermined length, and when it is coupled to a lead and a pad, one end thereof is placed on the lead, while the other end thereof is placed on the pad, the clip and the lead, and the clip and the pad are coupled each other at the same time. Coupling methods include solder bonding, Ag paste bonding, and ultrasonic bonding.

In the present invention, a ribbon means a wire connection material including the clip. However, a ribbon is more preferable, which can set arbitrarily the length and the loop shape according to the area of the lead or the pad, or the distance between the lead and the pad, than the clip in which the length and the loop shape are preliminarily determined.

The effect brought about by preferred embodiments of the present invention will be briefly described as follows.

The performance of surface mount package including a power MOSFET can be enhanced.

### BRIEF DESCRIPTION OF THE DRAWINGS

FIG. 1 is a plan view showing an appearance of a semiconductor device according to a first embodiment;

FIG. 2 is a side view showing the appearance of the semiconductor device according to the first embodiment;

FIG. 3 is a plan view showing an internal structure of the semiconductor device according to the first embodiment;

FIG. 4 is a section view along an A-A line in FIG. 3;

FIG. 5 is a section view along a B-B line in FIG. 3;

FIG. 6(a) is a schematic circuit diagram of a package including a power MOSFET;

FIG. 6(b) is a plan view showing a package of a comparative example;

FIG. 6(c) is a plan view showing a package of the first embodiment;

FIG. 7 is a main-part section view showing the power MOSFET formed in a silicon chip;

FIG. 8 is a plan view showing conductive films in an uppermost layer including a source pad, a gate pad and a gate wiring, and a gate electrode in a lower layer, formed in the silicon chip;

FIG. 9 is a flow chart showing an example of the manufacturing process of the semiconductor device of the first embodiment of the present invention;

FIG. 10 is a view illustrating a way how vibrational energy is imparted to an Ag paste when an Al ribbon is bonded to the source pad of the silicon chip by wedge bonding;

FIG. 11 is a view illustrating a guiding principle formula for selection of an optimum elastic modulus of the Ag paste;

FIG. 12 shows graphs illustrating the guiding principle formula for selection of four types of Ag paste and the results of a crack-resistance experiment;

FIG. 13 shows a graph illustrating the results of measurement of the shearing strength dependence of the elastic modulus of the Ag paste;

FIG. 14 is a plan view showing an internal structure of a semiconductor device of another embodiment of the present invention;

FIG. 15 is a plan view showing an internal structure of a semiconductor device of another embodiment of the present invention;

FIG. 16 is a plan view showing an internal structure of a semiconductor device of another embodiment of the present invention;

FIG. 17 is a plan view showing an outline a the rear surface side of a semiconductor device of another embodiment of the present invention;

FIG. 18 is a section view along a C-C line in FIG. 16;

FIG. 19 is an internal equivalent circuit diagram of a semiconductor device of another embodiment of the present invention;

FIG. 20 is a plan view showing an internal structure of a semiconductor device of another embodiment of the present invention;

FIG. 21 is a view describing an effect of a semiconductor device of another embodiment of the present invention;

FIG. 22 is a plan view of still a semiconductor device of another embodiment of the present invention;

FIG. 23 is a section view along a D-D line in FIG. 22;

FIG. 24 is a plan view of a semiconductor device of another embodiment of the present invention;

FIG. 25 is a plan view of another semiconductor device of another embodiment of the present invention;

FIG. 26 is a plan view of still another semiconductor device of another embodiment of the present invention;

FIG. 27 is a plan view of a semiconductor device of another embodiment of the present invention;

FIG. 28 is a plan view of a semiconductor device of another embodiment of the present invention;

FIG. 29 is an internal equivalent circuit diagram of the semiconductor device shown in FIG. 28;

FIG. 30 is a plan view of a semiconductor device of another embodiment of the present invention;

FIG. 31 is an internal equivalent circuit diagram of the semiconductor device shown in FIG. 30;

FIG. 32 is a plan view of a semiconductor device of another embodiment of the present invention;

FIG. 33 is an internal equivalent circuit diagram of the semiconductor device shown in FIG. 32;

FIG. 34 is a plan view of a semiconductor device of another embodiment of the present invention; and

FIG. 35 is an internal equivalent circuit diagram of the semiconductor device shown in FIG. 34.

FIG. 36 is a plan view of a semiconductor device exemplified as a comparative example of the present invention;

FIG. 37 is a plan view of a semiconductor device of another embodiment of the present invention;

FIG. 38 is a flow chart showing an example of a manufacturing process of the semiconductor device of another embodiment of the present invention;

FIG. 39 is a plan view showing a step of the manufacturing process of the semiconductor device of another embodiment of the present invention;

FIG. 40 is a plan view showing a step of the manufacturing process of the semiconductor device next to the step in FIG. 39;

FIG. 41 is a plan view showing a step of the manufacturing process of the semiconductor device next to the step in FIG. 40;

FIG. 42 is a section view showing a step of the manufacturing process of a semiconductor device of another embodiment of the present invention;

FIG. 43 is a section view showing a step of the manufacturing process of the semiconductor device next to the step in FIG. 41;

FIG. 44 is a section view showing a step of the manufacturing process of the semiconductor device next to the step in FIG. 43;

FIG. 45 is a section view showing a step of the manufacturing process of the semiconductor device next to the step in FIG. 44;

FIG. 46 is a plan view showing a step of the manufacturing process of the semiconductor device next to the step in FIG. 45;

FIGS. 47(a) to 47(c) are enlarged section views along an A-A line in FIG. 40: FIGS. 47(a) and 47(b) illustrate a problem in a case in which a die pad portion and a silicon chip are not aligned suitably each other; and FIG. 47(c) illustrates a case in which the die pad portion and the silicon chip are aligned suitably each other;

FIGS. 48(a) and 48(b) are enlarged section views along a B-B line in FIG. 42, and illustrate a problem in a case in which a die pad portion and a silicon chip are not aligned suitably each other, and a case in which the die pad portion and the silicon chip are aligned suitably each other, respectively.

### DETAILED DESCRIPTION OF THE PREFERRED EMBODIMENTS

Hereinafter, preferred embodiments of the present invention will be described in detail referring to the accompanying drawings. In all the drawings that illustrate the preferred embodiments, elements with like functions are attached with like reference numerals and duplicated descriptions of such elements are omitted. Moreover, in the preferred embodiments, unless necessary, descriptions of like or similar parts are not repeated in principle. Moreover, in the drawings that illustrate the preferred embodiments, for easier understanding of configuration, in some cases hatching is added even in a plan view.

### First Embodiment

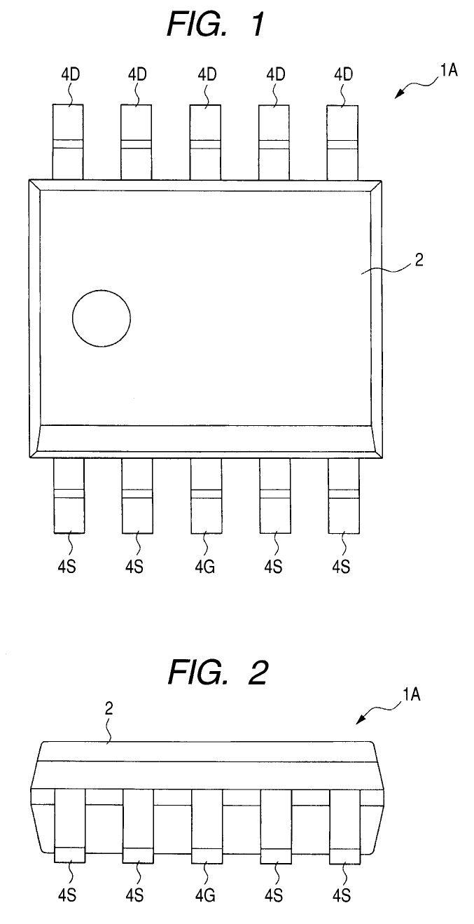

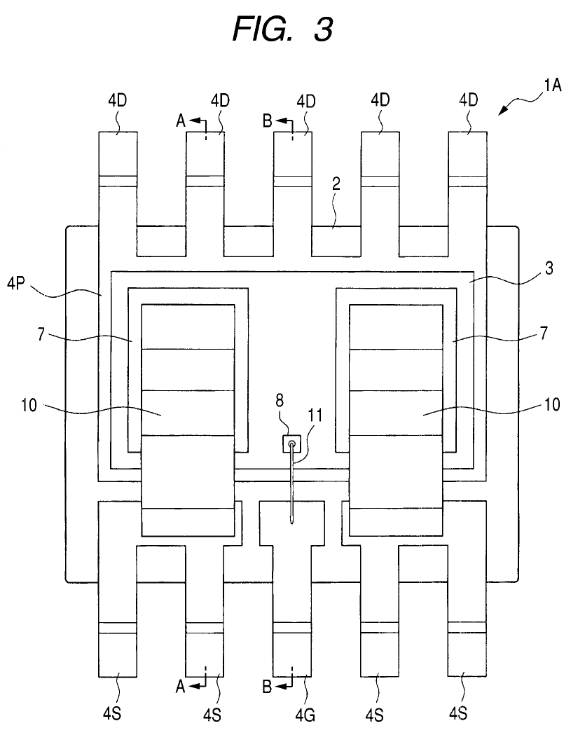

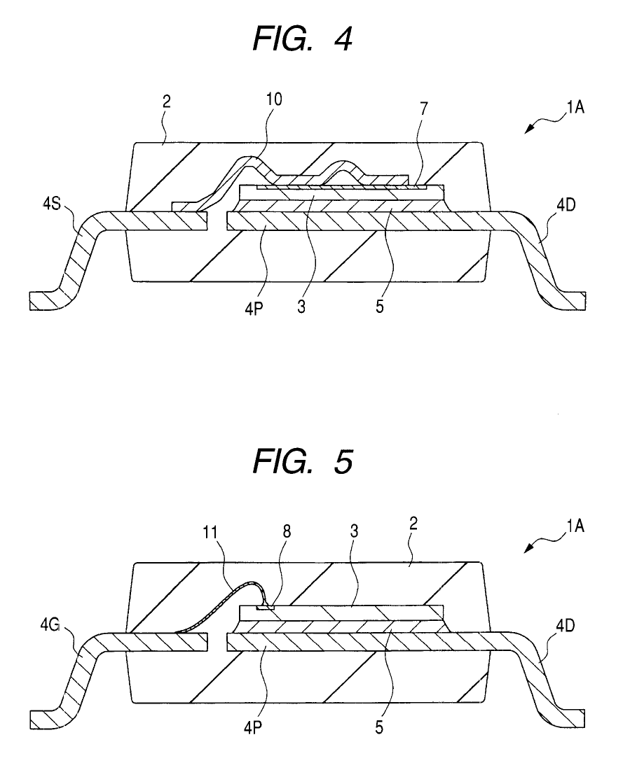

FIGS. 1 to 5 are views showing a semiconductor device of the present embodiment. FIG. 1 is a plan view showing an appearance thereof; FIG. 2 is a side view showing the appearance thereof; FIG. 3 is a plan view showing an internal structure thereof; FIG. 4 is a section view of FIG. 3 along an A-A line; and FIG. 5 is a section view of FIG. 3 along a B-B line.

A semiconductor device 1A of the present embodiment is a surface mount package where a silicon chip 3 is sealed with an epoxy-based molding resin 2, and, on each of two sides of the molding resin 2, there are exposed five outer lead portions of leads 4 constituting external connection terminals of the semiconductor device 1A. Among these ten leads 4, five leads arranged along the upper side of the molding resin 2 shown in FIG. 1 are drain leads 4D. Moreover, among five leads 4 arranged along the lower side of the molding resin 2, one central lead is a gate lead 4G and the remaining four leads are source leads 4S.

The planar sizes of the silicon chip 3 are, for example, long side×short side=3.9 mm×2.2 mm. Over the main surface of the silicon chip 3, there is formed a power MOSFET (which will be described below) used for a power control switch, a charge/discharge protection circuit switch of a portable information apparatus, and the like.

Moreover, the silicon chip 3 is mounted over a die pad portion 4P integrally formed with the five drain leads 4D, with its main surface upward. The rear surface of the silicon chip 3 constitutes the drain of the power MOSFET, and is joined to the top surface of the die pad portion 4P via an Ag paste 5. The die pad portion 4P and the ten leads 4 (drain lead 4D, gate lead 4G, and source lead 4S) are made of Cu or Fe—Ni alloy, over which surface, a plated layer (not shown in figures) having a three-layer structure (Ni/Pd/Au) is formed. With regard to the composition of the Ag paste 5 and the effect of the plated layer will be described later.

As shown in FIG. 3, over the main surface of the silicon chip 3, source pads 7 and a gate pad 8 are formed. As described below, each of the source pads 7 and the gate pad 8 are constituted with a conductive film mainly composed of an Al film, formed in the uppermost layer of the silicon chip 3. In order to reduce the on-resistance of the power MOSFET, the area of the source pad 7 is wider than that of the gate pad 8. From a similar reason, the entire rear surface of the silicon chip 3 constitutes the drain of the power MOSFET.

The semiconductor device 1A of the present embodiment includes two source pads 7 and one gate pad 8 which are formed over the main surface of the silicon chip 3, and the gate pad 8 is positioned between the two source pads 7.

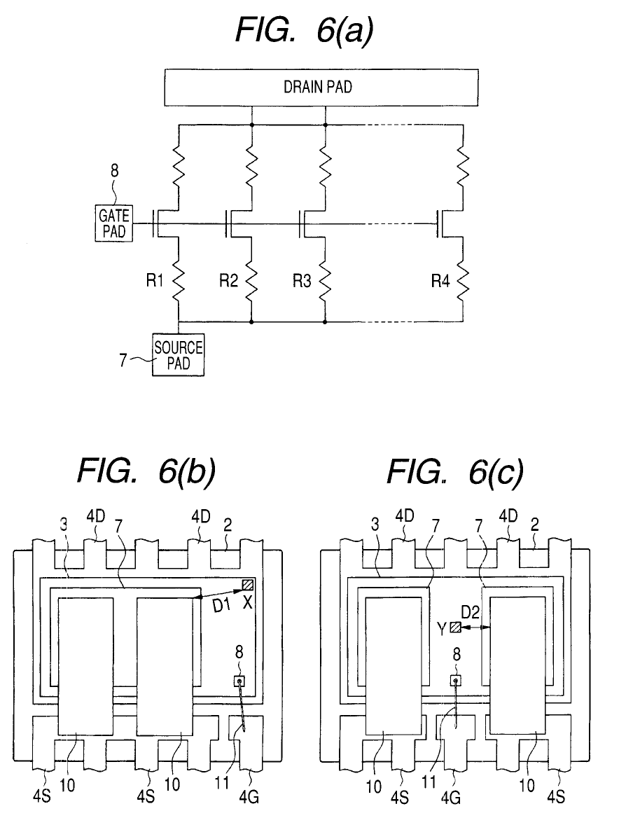

FIG. 6(a) is a schematic circuit diagram of a package including a power MOSFET. As shown in the figure, the configuration of the power MOSFET can be approximated so as to be configured with a plurality of MOSFETs being coupled in parallel with each other. Each of R1 to Rn in the figure represents a resistance from the source pad 7 to the source region of each power MOSFET, respectively. For example, R1 represents the resistance from the source pad 7 to the nearest source region, and Rn represents the resistance from the source pad 7 to the farthest source region.

FIG. 6(b) is a plan view showing a package of a comparative example, where a source pad 7 and a gate pad 8 are arranged asymmetrically with respect to the center of the main surface of the silicon chip 3; and FIG. 6(c) is a plan view showing a package of the present embodiment, where a gate pad 8 is positioned between the two source pads 7. In the comparative example shown in FIG. 6(b), since a distance (D1) from the position of the source pad 7 to the position (X) of the farthest source region is large, Rn will be extremely larger than R1, causing the source resistance of the entire package to be large. On the contrary, in the present embodiment shown in FIG. 6(c), since a distance (D2) from the position of the source pad 7 to the position (Y) of the farthest source region can be small, the increased amount of Rn with respect to R1 will be smaller than that of the comparative example. Thus, according the present embodiment where a gate pad 8 is positioned between the two source pads 7, the source resistance of the entire package can be made smaller than that of the comparative example shown in FIG. 6(b).

As shown in FIG. 3, in the semiconductor device 1A of the present embodiment, two source leads 4S arranged at the right side of the gate lead 4G and two source leads 4S arranged at the left side of the gate lead 4G are joined each other inside the molding resin 2, respectively, and each of the joined portions is electrically coupled to each source pad 7 via one Al ribbon 10. The thickness and the width of the Al ribbon 10 are about 0.1 mm and about 1 mm, respectively. In order to reduce the on-resistance of the power MOSFET, it is desirable for the width of the Al ribbon 10 to approach the width of the source pad 7 so that the contact area between the Al ribbon 10 and the source pad 7 will be as large as possible. On the contrary, the gate pad 8 having an area smaller than that of the source lead 4S is electrically coupled to the gate lead 4G via one Au wire 11.

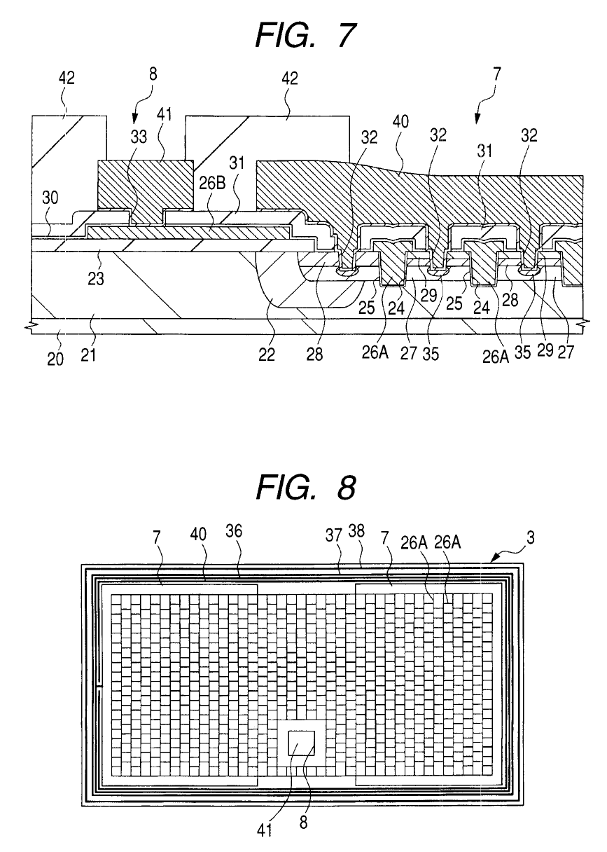

Next, the power MOSFET formed in the silicon chip 3 will be described. FIG. 7 is a main-part section view of the silicon chip 3, showing an n-channel type trench-gate power MOSFET that is an example of the power MOSFET.

Over the main surface of an n⁺-type single crystal silicon substrate 20, an n⁻-type single crystal silicon layer 21 is formed by an epitaxial growth process. The n⁺-type single crystal silicon substrate 20 and the n⁻-type single crystal silicon layer 21 constitute the drain of the power MOSFET.

A p-type well 22 is formed in a part of the n⁻-type single crystal silicon layer 21. Moreover, in a part of the surface of the n⁻-type single crystal silicon layer 21, a silicon oxide film 23 is formed, and, in another part of the surface, a plurality of trenches 24 is formed. The region of the surface of the n⁻-type single crystal silicon layer 21, which is covered with the silicon oxide film 23, constitutes an element isolation region, and the region in which trenches 24 are formed, constitutes an element formation region (an active region). Although, not being shown in the figure, the planar shape of the trench 24 is polygonal such as tetragonal, hexagonal, or octagonal, or a shape of a stripe extending toward one direction.

At the bottom portion and the side wall of each of the trenches 24, a silicon oxide film 25 constituting a gate oxide film of the power MOSFET is formed. Moreover, inside the trench 24, a polycrystalline silicon film 26A constituting a lower layer gate electrode of the power MOSFET is buried. On the contrary, over the silicon oxide film 23, a gate extraction electrode 26B is formed, which is made of a polycrystalline silicon film deposited by the same step as for the polycrystalline silicon film 26A constituting the lower layer gate electrode. The lower layer gate electrode (polycrystalline silicon film 26A) and the gate extraction electrode 26B are electrically coupled each other at a region not shown in the figure.

In the n⁻-type single crystal silicon layer 21 of the element formation region, a p⁻-type semiconductor region 27 being shallower than the trench 24 is formed. The p⁻-type semiconductor region 27 constitutes a channel layer of the power MOSFET. Over the p⁻-type semiconductor region 27, a p-type semiconductor region 28 having an impurity concentration higher than that of the p⁻-type semiconductor region 27 is formed, and further, over the p-type semiconductor region 28, an n⁺-type semiconductor region 29 is formed. The p-type semiconductor region 28 constitutes a punch-through stopper layer of the power MOSFET, and the n⁺-type semiconductor region 29 constitutes a source thereof.

Over the element formation region where the power MOSFET is formed, and over the element isolation region where the gate extraction electrode 26B is formed, two silicon oxide films 30 and 31 are formed. In the element formation region, connection holes 32 are formed, which penetrate through the silicon oxide films 30 and 31, the p-type semiconductor region 28, and the n⁺-type semiconductor region 29, and reach the p⁻-type semiconductor region 27. Moreover, in the element isolation region, a connection hole 33 is formed, which penetrates through the silicon oxide films 30 and 31, and reaches the gate extraction electrode 26B.

Over the silicon oxide film 31 including the inside of the connection holes 32, a source electrode 40 and a gate electrode 41 are formed, respectively, which are composed of a laminated film of a thin TiW (titanium tungsten) film and a thick Al film. The source electrode 40 formed in the element formation region is electrically coupled to the source (n⁺-type semiconductor region 29) of the power MOSFET through the connection holes 32. On the bottom portion of the connection hole 32, a p⁺-type semiconductor region 35 for contacting a source pad 7 to the p⁻-type semiconductor region 27 in an ohmic manner is formed. Moreover, the gate electrode 41 formed in the element isolation region is coupled to the lower layer gate electrode (polycrystalline silicon film 26A) of the power MOSFET via the gate extraction electrode 26B under the connection hole 33.

Over the source electrode 40 and the gate electrode 41, a surface protection film 42 is formed, which is composed of a laminated film of a silicon oxide film and a silicon nitride film. The source pad 7 is formed by removing a part of the surface protection film 42 to expose the source electrode 40, and the gate pad 8 is formed by removing another part of the surface protection film 42 to expose the gate electrode 41.

As mentioned above, to the source pad 7, one edge of an Al ribbon 10 is electrically coupled by a wedge bonding process. In order to buffer the impact imparted to the power MOSFET at the time of bonding with the Al ribbon 10, it is desirable for the source pad 7 to have a thickness of 3 μm or more over the silicon oxide films 30 and 31.

FIG. 8 is a plan view showing a conductive film of the uppermost layer including the source electrode 40 and the gate electrode 41 formed in the silicon chip 3. At the outer periphery of the silicon chip 3, Al wirings 36, 37 and 38 are formed. The Al wirings 36, 37 and 38 are composed of the conductive film (lamination of the TiW film and the Al film) in the same layer as that of the source electrode 40 and the gate electrode 41. In a practical silicon chip 3, since the source electrode 40, the gate electrode 41, and the Al wirings 36, 37 and 38 are covered with the surface protection film 42, on the surface of the silicon chip 3, only the source electrode 40 in the region where the source pad 7 is formed, and the gate electrode 41 in the region where the gate pad 8 is formed, are exposed among the above mentioned conductive films of the uppermost layer.

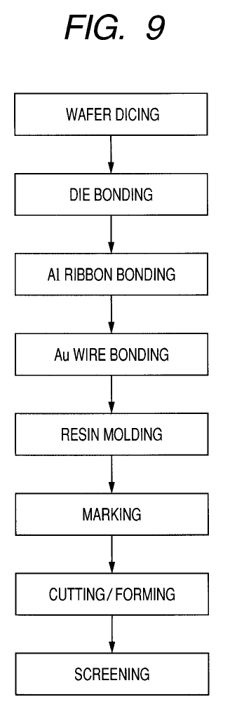

FIG. 9 is a flow chart showing an example of manufacturing process of the semiconductor device 1A of the present embodiment. In order to manufacture the semiconductor device 1A, a silicon chip 3 is obtained by, first, forming a power MOSFET on a silicon wafer according to a usual manufacturing method, and then dicing the silicon wafer. Next, a lead frame where leads 4 and a die pad portion 4P are formed is prepared, and the silicon chip 3 is die-bonded onto the die pad portion 4P using an Ag paste 5.

Next, using a wedge bonding process utilizing ultrasonic waves, the source pad 7 and the source leads 4S of the silicon chip 3 are electrically coupled by the Al ribbon 10. Subsequently, using a ball bonding process utilizing heat and ultrasonic waves, the gate pad 8 and the gate lead 4G of the silicon chip 3 are electrically coupled each other by the Au wire 11.

Next, using a mold die, the silicon chip 3 (including the die pad portion 4P, the Al ribbon 10, the Au wire 11, and the inner lead portion of the leads 4) are sealed with a molding resin 2, and then, the product name, the production number, and the like are marked on the surface of the molding resin 2. Subsequently, unnecessary portions of the leads 4 exposed outside the molding resin 2 are cut and removed, then, the leads 4 are formed in a shape of a gull-wing, and finally, a product is passed through a selection step of determining whether the product is acceptable or not, resulting in completion of the semiconductor device 1A.

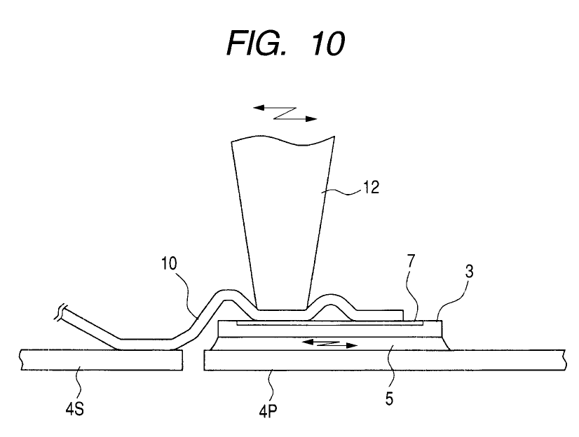

Thus, in the present embodiment, as a conductive material for electrically coupling the source pad 7 having an area larger than that of the gate pad 8 to the source lead 4S, the Al ribbon 10 having an area larger than that of the Au wire 11 is used. Thus, at the time of bonding the Al ribbon 10 on the surface of the source pad 7 by wedge bonding, as shown in FIG. 10, large vibrational energy of a bonding tool 12 is imparted not only on the surface of the silicon chip 3 but also to the Ag paste 5 intervening between the silicon chip 3 and the die pad portion 4P. Therefore, as a countermeasure to prevent cracks due to the large vibrational energy of bonding tool from occurring in the Ag paste 5, it is desirable to selectively use such an Ag paste 5 that has an optimum elastic modulus (Pa).

In the present embodiment, the elastic modulus (Pa) of the Ag paste 5 is defined by the following formula (1):

Elastic modulus (Pa)=2.6×thickness of bonding (μm)/(fracture dislocation (μm)×shearing strength (Pa)) (1)

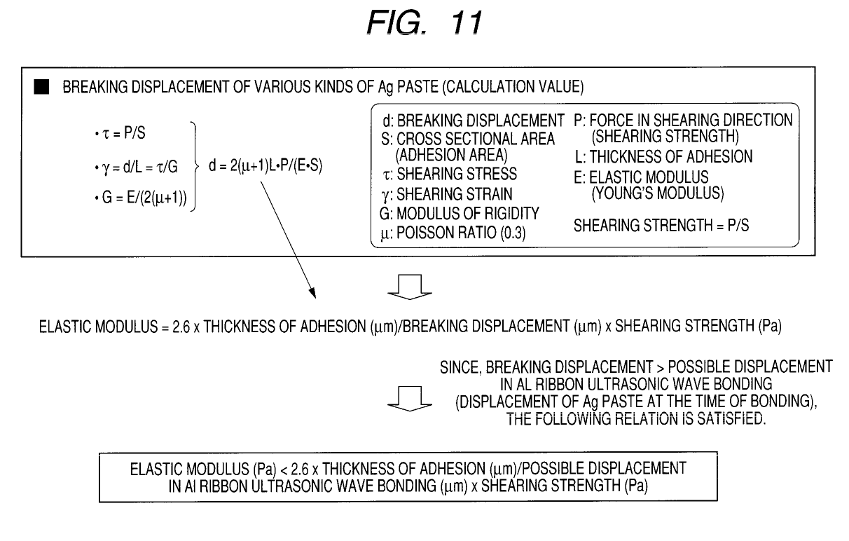

In FIG. (1), thickness of bonding (μm) is the thickness of Ag paste, and shearing strength (Pa) is expressed by (force in the shearing direction)/(section area (bonding area)). Moreover fracture dislocation is a value (μm) derived from the calculation formula shown in FIG. 11. Here, since fracture dislocation>possible dislocation by Al-ribbon ultrasonic bonding (=the distortion amount of the Ag paste due to vibration of the bonding tool when an Al ribbon is bonded to the Ag paste by ultrasonic bonding), the guiding principle formula for selection of elastic modulus (Pa) demanded for the Ag paste 5 of the present embodiment is expressed by {elastic modulus (Pa)<2.6×thickness of bonding (μm)/(possible dislocation (μm) by Al-ribbon ultrasonic bonding×shearing strength (Pa))}.

Next, a crack-resistance experiment performed for confirming the efficiency of the above mentioned guiding principle formula for selection will be described. Elastic moduli, shearing strength, and bonding thicknesses of four kinds of commercially available Ag pastes (1) to (4) are shown in Table 1. With regard to the distortion amount of an Ag paste when an Al ribbon is bonded to the Ag paste by ultrasonic bonding, it is 0.1218 μm for Ag pastes (1), (3) and (4), and it is 0.07 μm for Ag paste (2).

TABLE 1

| | Elastic | Shearing | Thickness of |
|---|---|---|---|
| | Modulus | Strength | Bonding |
| Ag paste (1) | 5.30 GPa | 15.5 MPa | 15.4 μm |
| Ag paste (2) | 5.34 GPa | 8.6 MPa | 13.2 μm |
| Ag paste (3) | 2.42 GPa | 14.2 MPa | 24.4 μm |
| Ag paste (4) | 0.611 GPa | 3.8 MPa | 16.6 μm |

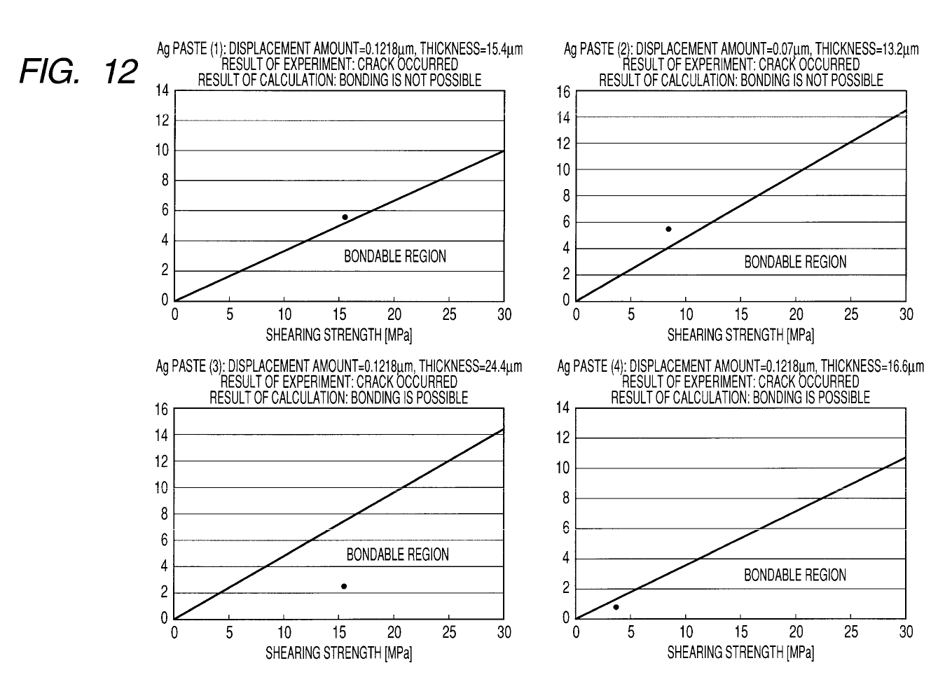

FIG. 12 shows graphs each illustrating guiding principle formula for selection and experimental result of each of the four kinds of Ag pastes (1) to (4). The elastic moduli of the Ag pastes (1) to (4) calculated by formula (1) are indicated by a solid line, respectively, and each region below the solid line represents a region where the guiding principle formula for selection is satisfied, that is a bondable region. Moreover, black points in each graph indicate the practical elastic modulus of each of the Ag pastes (1) to (4).

According to the experimental results, although, for the Ag pastes (3) and (4) of which practical elastic modulus satisfied the guiding principle formula for selection, cracks did not occur, for the Ag pastes (1) and (2) of which practical elastic modulus did not satisfy the guiding principle formula for selection, cracks occurred. From the experimental results, it is confirmed that, when the silicon chip 3 is bonded onto the pie pad portion 4P, by selecting the Ag paste 5 satisfying the guiding principle formula for selection, cracks of the Ag paste 5 due to the vibrational energy of the bonding tool can be effectively prevented from occurring.

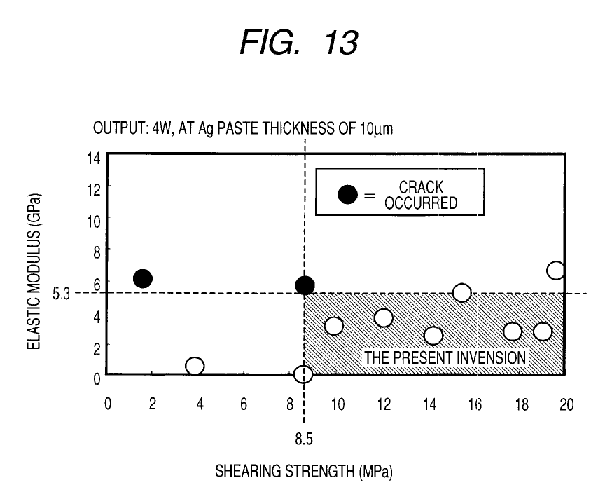

FIG. 13 shows a graph illustrating the results of measurement of the shearing strength dependence of the elastic modulus of an Ag paste when the thickness of the Ag paste is set to 10 μm, and the Al ribbon is bonded to the Ag Paste at a standard output (4 W) of ultrasonic waves. In the graph, white circles indicate examples where cracks did not occur, and black circles indicate examples where cracks occurred.

From the results of measurement, it is determined that it is desirable for the elastic modulus of the Ag paste to be within a range of 0.2 to 5.3 GPa, and for the shearing strength of the Ag paste to be 8.5 MPa or more. When the elastic modulus is smaller than 0.2 GPa, the Ag paste cannot have a desired conductivity because the Ag content is too small. On the other hand, when the elastic modulus is greater than 5.3 GPa, the Ag paste cannot be deformed because the hardness of the Ag paste is too large, thereby, the Ag paste cannot follow the vibration at the time of ultrasonic bonding, resulting in occurrence of cracks. Moreover, when the shearing strength of the Ag paste is smaller than 8.5 MPa, the Ag paste cannot withstand the impact occurring at the time of ultrasonic bonding.

Next, an effect of a case where a plated layer mainly composed of a Pd film is formed on the surface of the lead frame (the die pad portion 4P and the leads 4) will be described. In Table 2, when three kinds (Ag, Ni, and Pd) of single plated layers are formed on a surface of the lead frame made of Cu, and when no plated layer is formed (in a case of bare Cu), bonding properties between the source lead and the Al ribbon, between the gate lead and the Au wire, and between the die pad portion and the Ag baste, are shown, respectively (∘ indicates a good bonding property, and × indicates a failure of bonding).

TABLE 2
Source: Al ribbon, Gate: Au wire,
Die bonding material: Ag paste

Plating Material

| | Ag | Ni | Pd | Bare Cu |
|---|---|---|---|---|
| Connection between a source | x | ∘ | ∘ | ∘ |
| post and an Al ribbon | | | | |
| Connection between a gate post | ∘ | x | ∘ | x |
| and an Au wire | | | | |
| Connection between a die pad and | ∘ | x | ∘ | x |
| an Ag paste | | | | |

As is clear from Table 2, when a plated layer mainly composed of a Pd film is formed on the surface of lead frame, it can be seen that good bonding properties are demonstrated between the source lead (source post) and the Al ribbon, between the gate lead (gate lead) and the Au wire, and between the die pad portion and the Ag baste.

TABLE 3
Source: Al ribbon, Gate: Al wire,
Die bonding material: Ag paste

Plating Material

| | Ag | Ni | Pd | Bare Cu |
|---|---|---|---|---|
| Connection between a source | x | ∘ | ∘ | ∘ |
| post and an Al ribbon | | | | |
| Connection between a gate post | ∘ | ∘ | ∘ | ∘ |
| and an Al wire | | | | |
| Connection between a die pad and | ∘ | x | ∘ | x |
| an Ag paste | | | | |

Moreover, as is clear from Table 3, when a plated layer composed of a Pd film is formed on the surface of lead frame, it is demonstrated that a good bonding property is also obtained even if the gate pad and the gate lead is coupled by an Al wire. Thus, by forming a plated layer mainly composed of a Pd film on the surface of lead frame, one kind of plating material can be used for all of the connections, thereby, enabling a manufacturing process to be simplified.

Thus, according to the present embodiment, by coupling the source lead 4S and the source pad 7 by the Al ribbon 10, the bonding area will be smaller than that when they are connected by the Au wire, thereby, a low resistance semiconductor device 1A can be achieved. Moreover, since the cost of the Al ribbon 10 is lower than that of the Au wire, the manufacturing cost of the semiconductor device 1A can be reduced. Moreover, if demanded resistance value is equal to a case where the source lead 4S and the source pad 7 are connected by the Au wire, the size of the source pad 7 furthermore the size of the silicon chip 3 can be reduced, thereby, in this case, the manufacturing cost of the semiconductor device 1A can also be reduced.

Moreover, according to the present embodiment, by optimizing the elastic modulus and the shearing strength of the Ag paste 5, the cracks of the Ag paste 5 originating from ultrasonic bonding of the Al ribbon 10 can be prevented from occurring, and thereby the manufacturing yield and the reliability of the semiconductor device 1A are improved.

Moreover, according to the present embodiment, by forming a plated layer mainly composed of a Pd film on the surface of the lead frame (die pad portion 4P and leads 4), a Pb-free semiconductor device 1A can be achieved.

### Second Embodiment

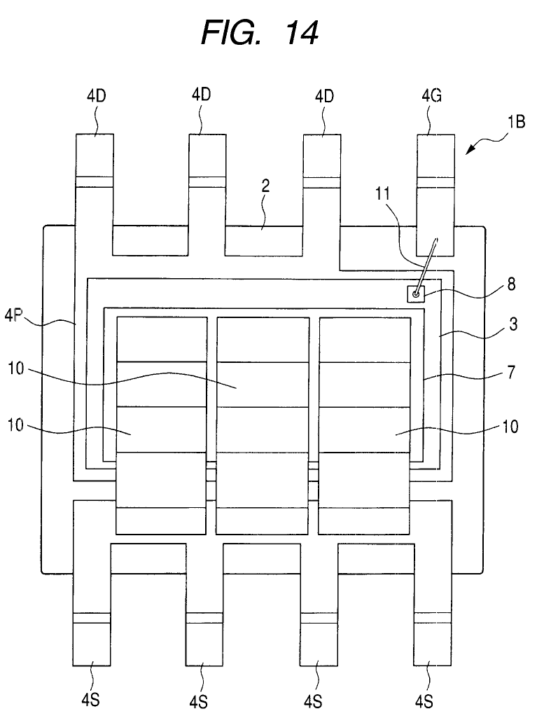

FIG. 14 is a plan view showing an internal structure of a semiconductor device of the present embodiment. A semiconductor device 1B of the present embodiment and the semiconductor device 1A of the first embodiment differ in the number of external connection terminals (leads 4) and in the arrangement thereof.

Namely, in the semiconductor device 1B of the present embodiment, on each of the two side surfaces of a molding resin 2, four outer lead portions of leads 4 are exposed. Among the eight leads 4, four leads 4 arranged along the upper side of a package shown in FIG. 14 are three drain leads 4D and one gate lead 4G. Moreover, four leads 4 arranged along the lower side of the package are source leads 4S. In addition, the silicon chip 3 is mounted on a die pad portion 4P integrally formed with the three drain leads 4D. Although not shown in the figure, the rear surface of the silicon chip 3 constitutes the drain of a power MOSFET, and it is joined to the top surface of the die pad portion 4P via the same Ag paste 5 that is used in the first embodiment.

Over the main surface of the silicon chip 3, a source pad 7 and a gate pad 8 are formed. As mentioned above, in the semiconductor device 1B of the present embodiment, the drain leads 4D and the gate lead 4G are arranged on a single side surface of the molding resin 2. Therefore, the gate pad 8 is positioned at a corner portion near the gate lead 4G, and electrically coupled to the gate lead 4G via an Au wire 11.

On the other hand, the four source leads 4S arranged along the lower side of the package shown in FIG. 14 are joined to each other inside the molding resin 2, and the joined portion is electrically coupled to the source pad 7 via Al ribbons 10.

In the present embodiment, since the gate pad 8 is positioned at the corner portion over the main surface of the silicon chip 3, the area of the source pad 7 formed over the main surface of the silicon chip 3 is larger than that of the first embodiment. Therefore, the source leads 4S and the source pad 7 are coupled via three Al ribbons 10.

Moreover, among the three Al ribbons 10, the center Al ribbon 10 is positioned at the center of the main surface of the silicon chip 3, and the rest two Al ribbons 10 are arranged equally apart from the center Al ribbon 10. Since by arranging the three Al ribbons 10 in this manner, similar effect as that of the first embodiment can be obtained, the on-resistance of the power MOSFET is reduced.

Moreover, according to the present embodiment, since the area of the source pad 7 is increased than that of the first embodiment, the number of the Al ribbons 10 coupled to the source pad 7 can be increased. This leads to increase of the contact area between the source pad 7 and the Al ribbons 10, which causes the on-resistance of the power MOSFET to be small, and thereby a semiconductor device 1B having improved device performance can be achieved.

### Third Embodiment

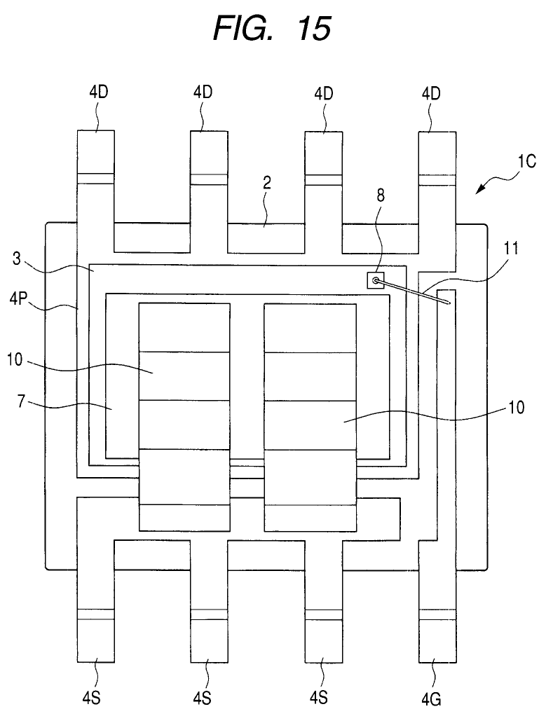

FIG. 15 is a plan view showing an internal structure of a semiconductor device of the present embodiment. A semiconductor device 1C of the present embodiment and the semiconductor device 1A of the first embodiment differ in the number of the external connection terminals (leads 4) and the arrangement thereof.

In the semiconductor device 1C of the present embodiment, on each of the two side surfaces of a molding resin 2, four outer lead portions of leads 4 are exposed. Among the eight leads 4, four leads 4 arranged along the upper side of a package shown in FIG. 15 are drain leads 4D. Moreover, four leads 4 arranged along the lower side of the package are three source leads 4S and one gate lead 4G. Namely, the semiconductor device 1C of the present embodiment has the same arrangement of external connection terminals as that of an existing SOP 8.

The silicon chip 3 is mounted on a die pad portion 4P integrally formed with the four drain leads 4D. Although not shown in the figure, the rear surface of the silicon chip 3 constitutes the drain of a power MOSFET, and it is joined to the top surface of the die pad portion 4P via the same Ag paste 5 that is used in the first embodiment.

Over the main surface of the silicon chip 3, a source pad 7 and a gate pad 8 are formed. The gate pad 8 is positioned at a corner portion near the gate lead 4G, and electrically coupled to the gate lead 4G via an Au wire 11. On the other hand, the three source leads 4S arranged along the lower side of the package shown in FIG. 15 are joined each other inside the molding resin 2, and the joined portion is electrically coupled to the source pad 7 via two Al ribbons 10.

The two Al ribbons 10 are arranged equally apart from the center of the source pad 7. Since, by arranging the two Al ribbons 10 in this manner, a similar effect as that of the first embodiment can be obtained, the on-resistance of the power MOSFET is reduced. Namely, according to the present embodiment, while keeping the arrangement of the external connection terminals to be the same arrangement as that of an existing SOP 8, the device performance can be improved.

### Fourth Embodiment

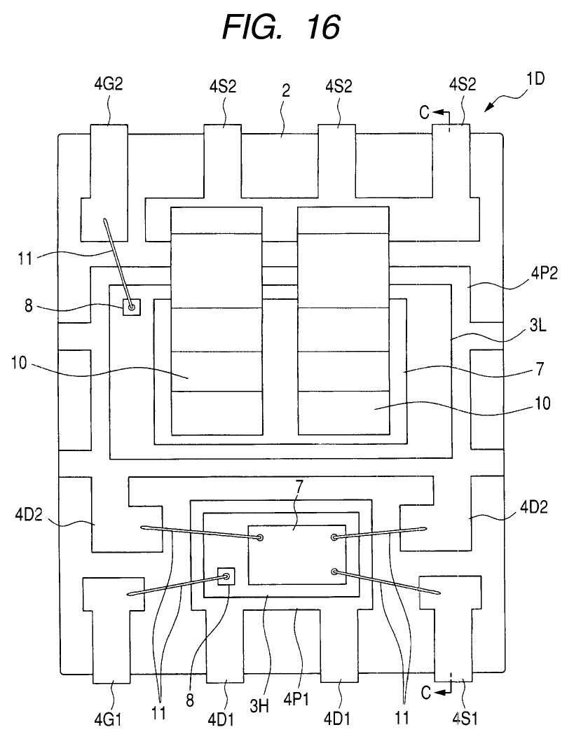

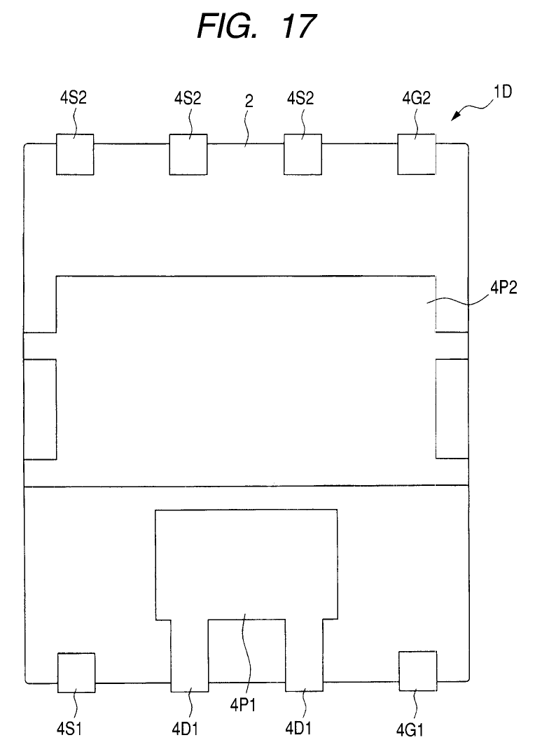

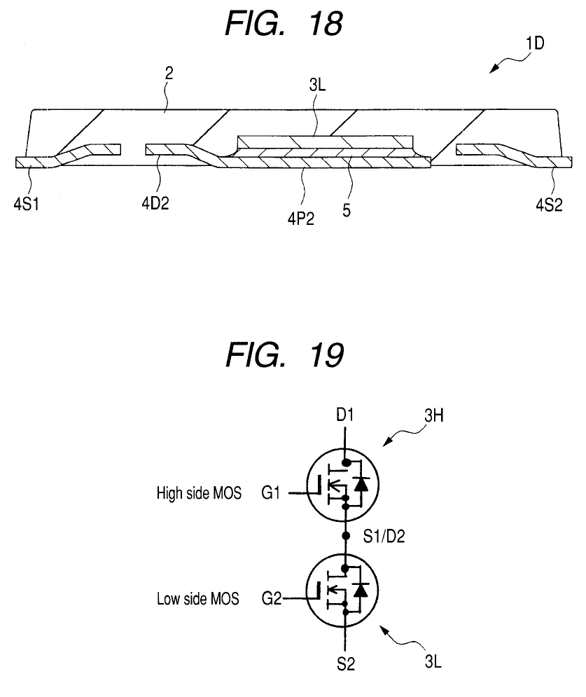

FIGS. 16 to 19 are views showing a semiconductor device of the present embodiment. FIG. 16 is a plan view showing an internal structure thereof; FIG. 17 is a plan view showing a rear surface side appearance thereof; FIG. 18 is a section view along a C-C line of FIG. 16; and FIG. 19 is an internal equivalent circuit diagram thereof.

A semiconductor device 1D of the present embodiment is a surface mount package where two silicon chips 3H and 3L are sealed with a molding resin 2, and, on each of two side surfaces of the molding resin 2, four outer leads of leads 4 constituting external connection terminals, are exposed.

Among the two silicon chips 3H and 3L, over the main surface of the silicon chip 3H having a smaller area, a high-side MOSFET is formed, and over the main surface of the silicon chip 3L having a larger area, a low-side MOSFET is formed. As shown in FIG. 19, the source of the high-side MOSFET and the drain of the low-side MOSFET are electrically coupled each other, which constitutes, for example, a DC/DC converter. Since the specific structures of the high-side MOSFET and the low-side MOSFET are approximately equal to the structure of the power MOSFET of the first embodiment, their illustrations are omitted.

Moreover, among the two silicon chips 3H and 3L, the silicon chip 3H having a smaller area is mounted on a die pad portion 4P1 integrally formed with the two drain leads 4D1, with its main surface upward. The rear surface of the silicon chip 3H constitutes the drain of the high-side MOSFET, and it is joined to the top surface of the die pad portion 4P1 via the same Ag paste 5 that is used in the first embodiment.

At the lower side of the molding resin 2 shown in FIG. 16, one gate lead 4G1 and one source lead 4S1 are arranged at both sides while sandwiching the two drain leads 4D1. Moreover, over the main surface of the silicon chip 3H, a source pad 7 having a larger area and a gate pad 8 having a smaller area are formed. In addition, the source pad 7 and the source lead 4S1 of the silicon chip 3H are electrically coupled each other via one Au wire 11, and the gate pad 8 and the gate lead 4G1 of the silicon chip 3H are electrically coupled each other via one Au wire 11.

On the other hand, the silicon chip 3L having a larger area is mounted on a die pad portion 4P2 having a larger area than that of the die pad portion 4P1, with its main surface upward. Over the main surface of the silicon chip 3L, a source pad 7 having a larger area and a gate pad 8 having a smaller area are formed. Moreover, the rear surface of the silicon chip 3L constitutes the drain of the low-side MOSFET, and it is joined to the top surface of the die pad portion 4P2 via the same Ag paste 5 that is used in the first embodiment.

At the upper side of the molding resin 2 shown in FIG. 16, three source lead 4S2 and one gate lead 4G2 are arranged. The three source leads 4S2 are joined each other inside the molding resin 2, and the joined portion and the source pad 7 of the silicon chip 3L are electrically coupled each other via two Al ribbons 10. Moreover, the gate pad 8 of the silicon chip 3L is electrically coupled to the gate lead 4G2 via one Au wire 11.

Moreover, as shown in FIG. 16, near the die pad portion 4P1 on which the silicon chip 3H is mounted, two drain leads 4D2 integrally formed with the die pad portion 4P2 on which the silicon chip 3L is mounted are arranged. In addition, each of the drain leads 4D2 and the source pad 7 of the silicon chip 3H are electrically coupled each other via the Au wire 11, which causes the source of the high-side MOSFET and the drain of the low-side MOSFET to be electrically coupled each other (refer to FIG. 19).

Moreover, as shown in FIG. 17, on the rear surface of the molding resin 2, rear surfaces of the two die pad portions 4P1 and 4P2 are exposed. Therefore, since the rear surfaces of the two die pad portions 4P1 and 4P2 can be soldered to a wiring on a wiring board when the semiconductor device 1D is mounted on the wiring board etc., heat occurred in the two silicon chips 3H and 3L can be effectively dissipated outside the chips, enabling the heat resistance of the package to be reduced.

Thus, in the semiconductor device 1D of the present embodiment, the source pad 7 and each of the source leads 4S2 of the silicon chip 3L having a larger area among the two silicon chips 3H and 3L, are connected each other by the Al ribbon 10. Therefore, the on-resistance of the low-side MOSFET can be reduced as compared to the case where the source pad 7 and each of the source leads 4S2 are connected each other by the Au wire. In addition, when the connection of the source pad 7 of the silicon chip 3L and the source leads 4S2 is performed by two Al ribbons 10, it is desirable for the two Al ribbons 10 to be arranged equally apart from the center of the silicon chip 3L. Therefore, the on-resistance of the low-side MOSFET can be reduced further.

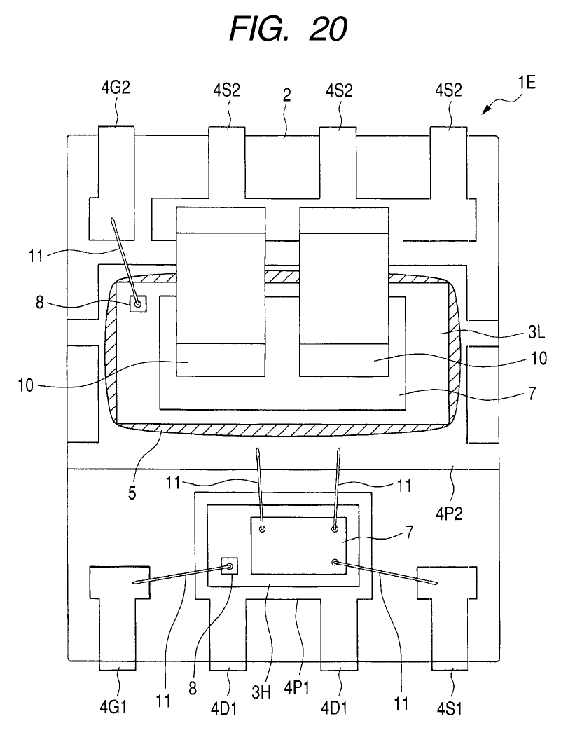

When the source of the high-side MOSFET and the drain of the low-side MOSFET are electrically coupled each other, as shown in FIG. 20, the source pad 7 of the silicon chip 3H mounted on the die pad portion 4P1 may be directly connected to the die pad portion 4P2 by the Au wire 11, over which the silicon chip 3L is mounted.

However, in this case, since the silicon chip 3L and the Au wire 11 are close to each other, under some bonding conditions, the Au wire 11 may contact the conductive Ag paste 5 seeped out from a gap between the silicon chip 3L and the die pad portion 4P2, resulting in reduction of connection reliability of the Au wire 11. In order to surely avoid such a trouble, the size of the silicon chip 3L mounted on the die pad portion 4P2 must be small, however, in this case, since the contact area between the source pad 7 of the silicon chip 3L and the Al ribbon 10 will also be small, it will be difficult to reduce the on-resistance of the low-side MOSFET.

Accordingly, when the source of the high-side MOSFET and the drain of the low-side MOSFET are electrically coupled each other, as shown in FIG. 16, it is desirable to arrange drain leads 4D2 integrally formed with the die pad portion 4P2 and to connect each of the drain leads 4D2 to the source pad 7 of the silicon chip 3H by the Au wires 11.

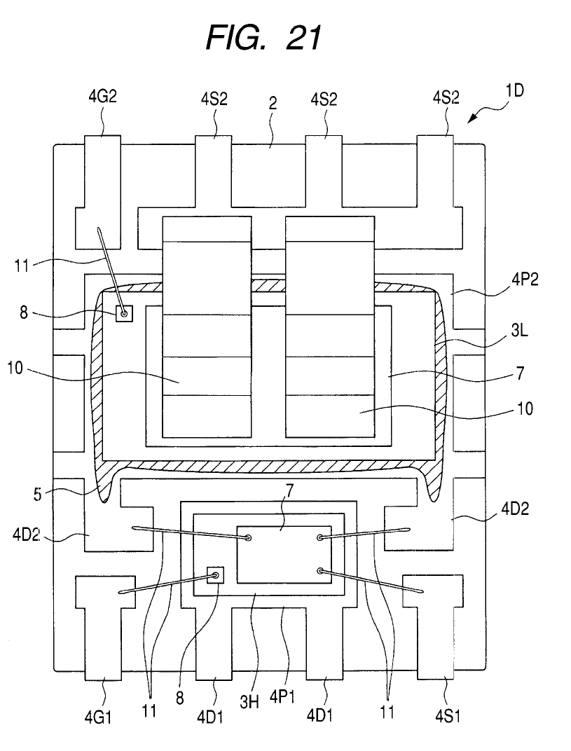

Moreover, in the present embodiment, as shown in FIG. 18, each of the drain leads 4D2 is subjected to bending so that its height will be higher than that of the die pad portion 4P2. In such a case, as shown in FIG. 21, since, even if a large amount of Ag paste 5 seeps out from the gap between the silicon chip 3L and the die pad portion 4P2, the Ag paste 5 does not reach the bonding region of each of the drain leads 4D2, interference between the Ag paste 5 and the Au wire 11 can be surely prevented.

Also, in such a case, as shown in FIG. 17, even if the die pad portion 4P1 is exposed on the rear surface of the molding resin 2, the drain leads 4D2 are not exposed. Accordingly, when the rear surfaces of the die pad portions 4P1 and 4P2 are soldered to the wiring board, it is surely possible to prevent a failure, that is short-circuit of the die pad portion 4P1 and the neighboring drain leads 4D2 via solder, from occurring.

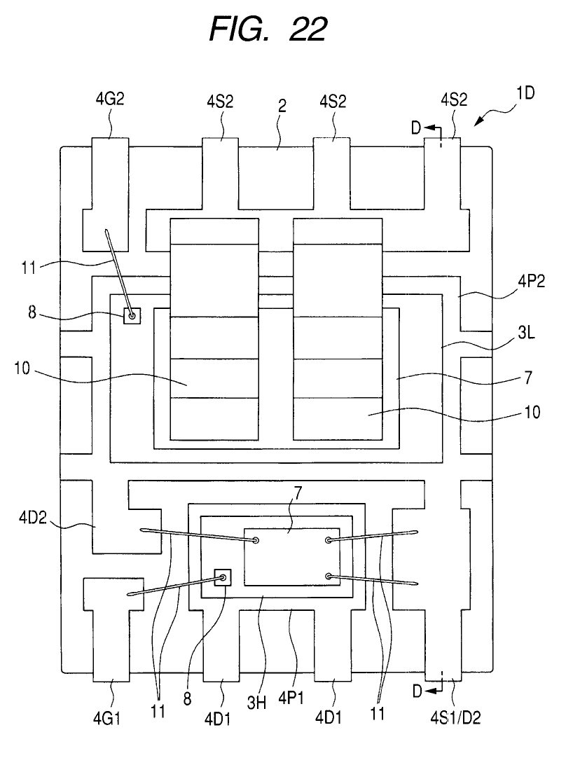

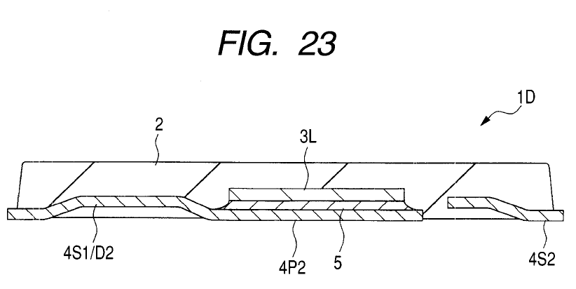

The configuration of the semiconductor device 1D of the present embodiment is not limited to the above-mentioned configuration, for example, instead, as shown in FIG. 22 and FIG. 23 (the section view along the D-D line of FIG. 22), a configuration may also be used, where the drain leads 4D2 and the source lead 4S1 are integrated into one lead (4S1/D2), and by connecting the lead (4S1/D2) and the source pad 7 of the silicon chip 3H each other by the Au wire 11, the source of the high-side MOSFET and the drain of the low-side MOSFET are also electrically coupled each other.

In this case, in order to prevent interference between the Ag paste 5 and the Au wire 11, and short-circuit due to solder between the lead (4S1/D2) and the die pad portion 4P1 from occurring, as shown in FIG. 23, it is also desirable that the height of the lead (4S1/D2) is higher than that of the die pad portion 4P2 within the molding resin 2.

### Fifth Embodiment

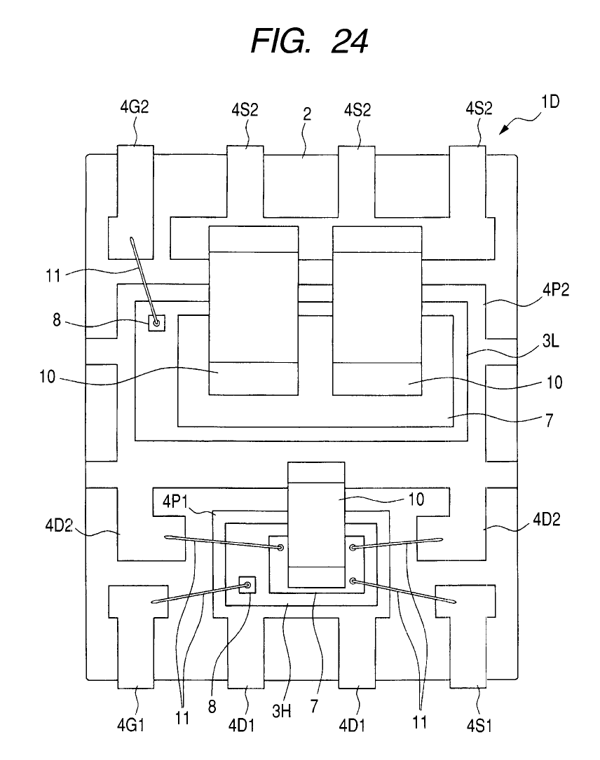

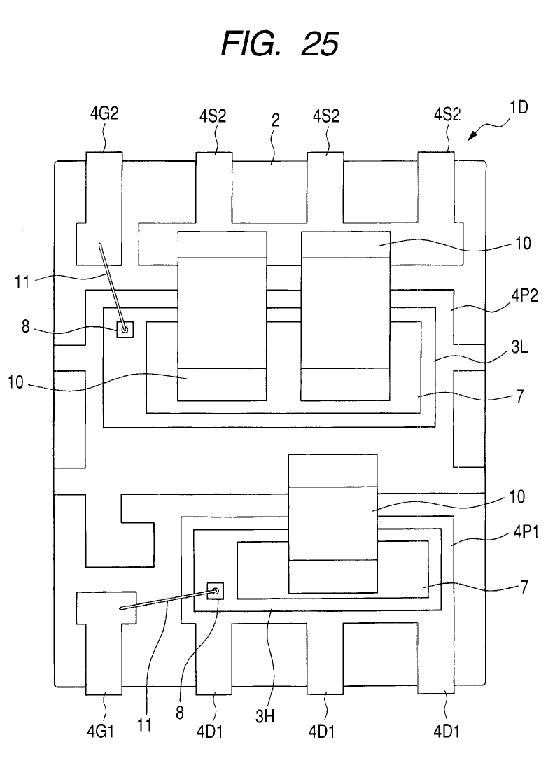

For example, when the size of the silicon chip 3L is comparatively small, or when the size of the silicon chip 3H is comparatively large, as shown in FIGS. 24 and 25, a configuration may also be used where the source pad 7 of the silicon chip 3H and the die pad portion 4P2 are directly connected each other by an Al ribbon 10. In this case, not only the on-resistance of the low-side MOSFET formed in the silicon chip 3L but also the on-resistance of the high-side MOSFET formed in the silicon chip 3H can be reduced.

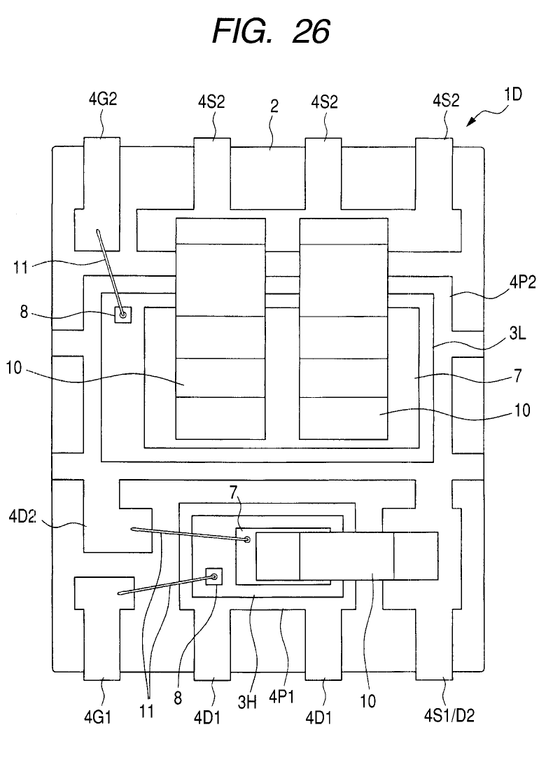

Moreover, for example, as shown in FIG. 26, when a drain lead 4D2 and a source lead 4S1 are integrated into one lead (4S1/D2), the area of the lead (4S1/D2) will be large, and thereby, by connecting the source pad 7 of the silicon chip 3H and the lead (4S1/D2) each other by an Al ribbon 10, the on-resistance of the high-side MOSFET can be reduced.

### Sixth Embodiment

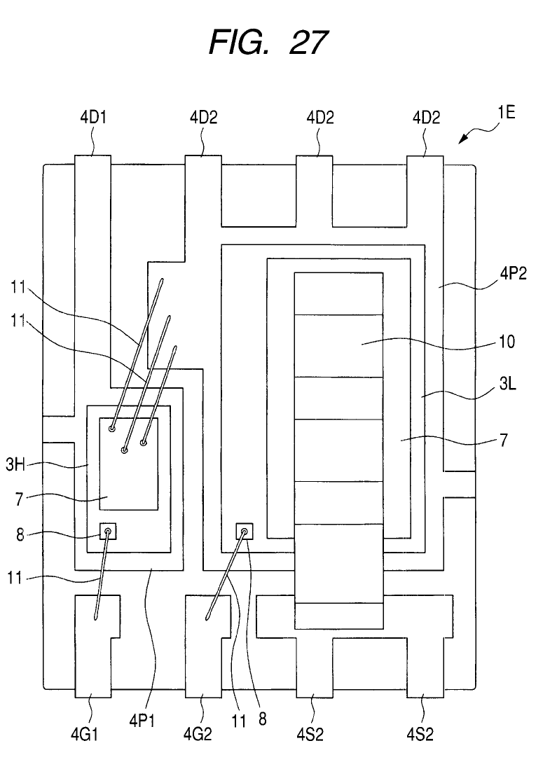

As shown in FIG. 27, in a semiconductor device 1E of the present embodiment, when a silicon chip 3L is mounted on a die pad portion 4P2, the long side of the silicon chip 3L may be arranged in parallel with the direction along which eight leads 4 are extended. In this case, since the extending direction of an Al ribbon 10 connecting a source pad 7 and source leads 4S2 of the silicon chip 3L is in parallel with the long side of the silicon chip 3L, even if only one Al ribbon 10 is connected to the source pad 7, by increasing the contact area between the source pad 7 and the Al ribbon 10, the on-resistance of a low-side MOSFET can be reduced.

### Seventh Embodiment

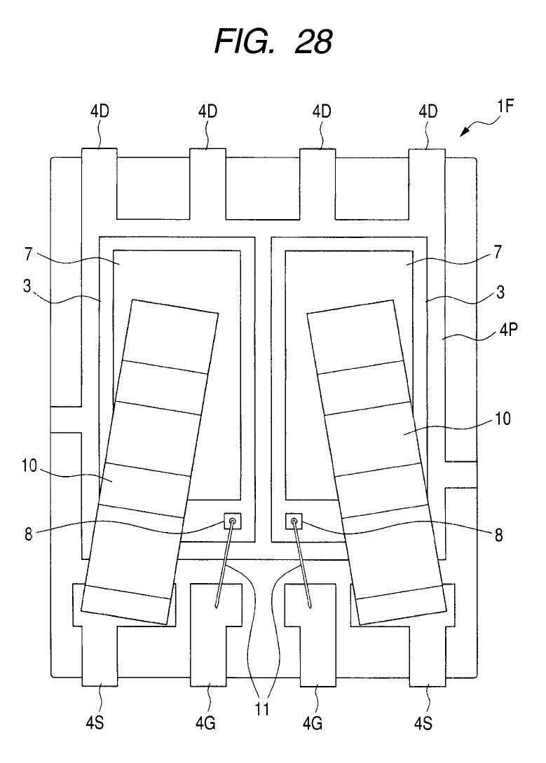

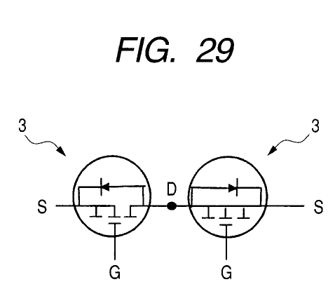

A semiconductor device 1F shown in FIG. 28 is an example where two silicon chips 3 are mounted on a die pad portion 4P which is integrally formed with drain leads 4D, and FIG. 29 is an internal equivalent circuit diagram of the semiconductor device 1F.

The rear surfaces of the two silicon chips 3 constitute the drain of a Power MORFET, and it is joined to the top surface 4P of the die pad portion 4P via the same Ag paste 5 that is used in the first embodiment. Moreover, over the main surface of each of the two silicon chips 3, a source pad 7 and a gate pad 8 are formed. In addition, each of the source pads 7 is electrically connected to a source lead 4S via an Al ribbon 10, and each of the gate pads 8 is electrically connected to a gate lead 4G via an Au wire 11.

In this case, by connecting the source pad 7 and the source lead 4S of each of the two silicon chips 3 via the Al ribbon 10, the on-resistance of the power MOSFET of each of the silicon chips 3 can also be reduced.

### Eighth Embodiment

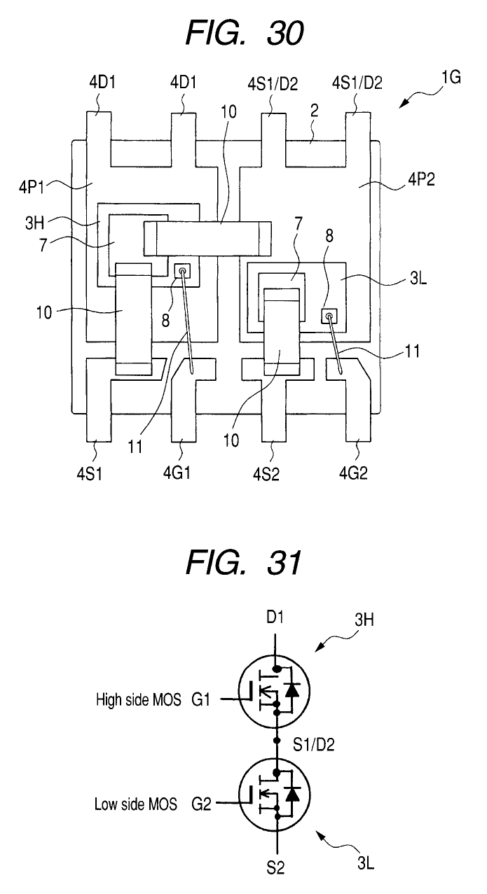

A semiconductor device 1G shown in FIG. 30 is an example where a source pad 7 and a source lead 4S1 of a silicon chip 3H formed over a die pad portion 4P1, a source pad 7 and a source lead 4S2 of a silicon chip 3L formed over a die pad portion 4P2, and the source pad 7 of the silicon chip 3H and the die pad portion 4P2 are electrically connected each other by an Al ribbon 10, respectively, and FIG. 31 is an equivalent internal circuit diagram of the semiconductor device 1G.

According to the semiconductor device 1G, both of the on-resistance of a low-side MOSFET formed over the silicon chip 3L, and the on-resistance of a high-side MOSFET formed over the silicon chip 3H, can be reduced.

### Ninth Embodiment

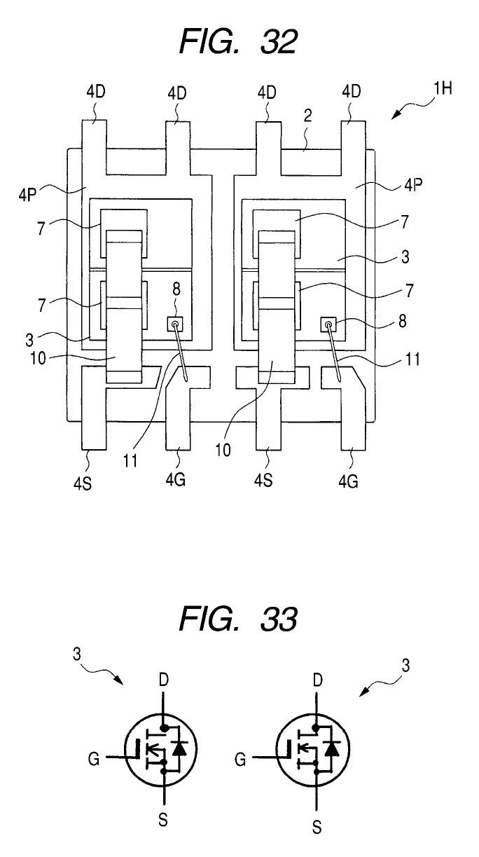

A semiconductor device 1H shown in FIG. 32 is an example where a silicon chip 3 is mounted on each two die pad portions 4P integrally formed with drain leads 4D, source pads 7 and a source lead 4S of each of the silicon chips 3 are electrically connected each other by an Al ribbon 10, and FIG. 33 is an equivalent internal circuit diagram of the semiconductor device 1H.

According to the semiconductor device 1H, both of the on-resistance of a power MOSFET formed over each of the two silicon chips 3, can be reduced.

The invention made by the present inventor has been so far described in reference to preferred embodiments thereof. However, the invention is not limited thereto and it is obvious that these details may be modified in various ways without departing from the spirit and scope of the invention.

### Tenth Embodiment

Although the above embodiments 1 to 9 are applied to a surface mount package where one or two silicon chips are sealed with a molding resin, the invention is also applicable to a surface mount package where three silicon chips are sealed with a molding resin.

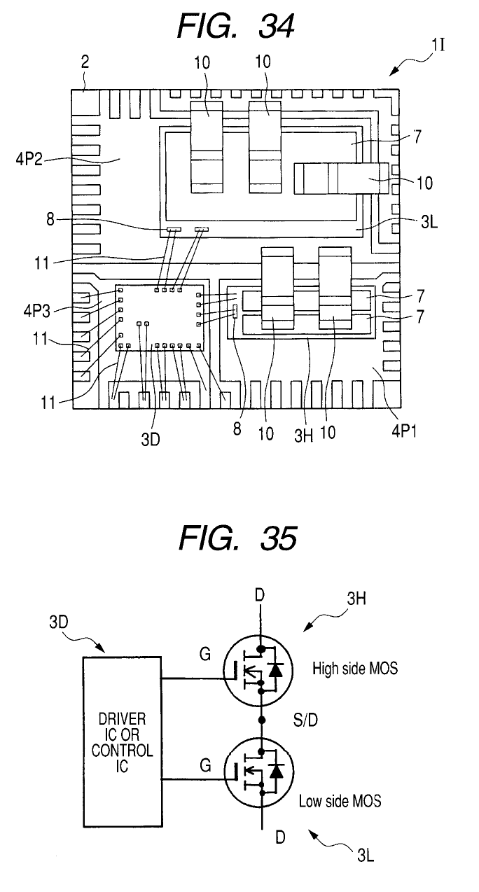

A semiconductor device 1I shown in FIG. 34 is a SIP (System In Package) where three silicon chips 3D, 3H and 3L are sealed with a molding resin 2, and FIG. 35 is an equivalent internal circuit diagram of the semiconductor device 1I.

The three silicon chips 3D, 3H and 3L are mounted on die pad portions 4P1, 4P2 and 4P3 via the above-mentioned Ag paste 5, respectively. With regard to the three silicon chips 3D, 3H and 3L, a high-side MOSFET is formed over the main surface of the silicon chip 3H, a low-side MOSFET is formed over the main surface of the silicon chip 3L, and a driver IC or a control IC is formed over the main surface of the silicon chip 3L.

In this case also, since, by connecting an Al ribbon 10 to the source pad 7 of each of the silicon chips 3H, 3L, both of the on-resistances of the low-side MOSFET formed in the silicon chip 3L and the high-side MOSFET formed in the silicon chip 3H can also be reduced, the properties of the SIP can be improved.

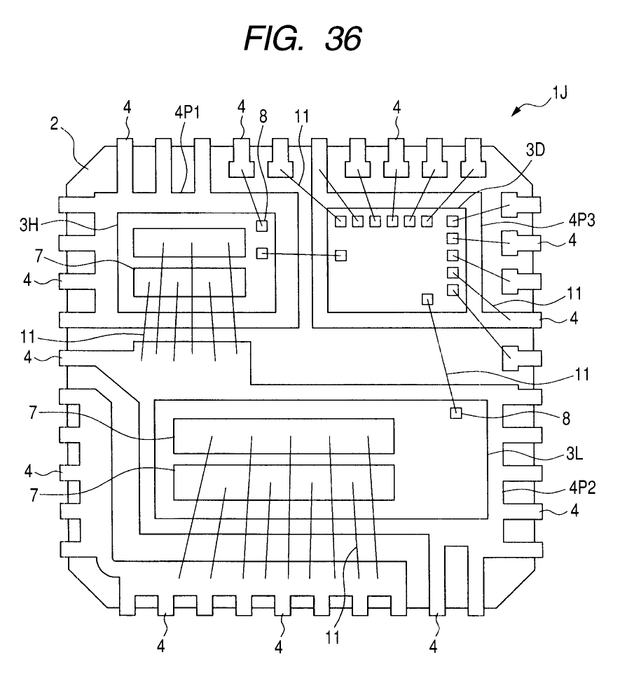

A semiconductor device 1J shown in FIG. 36 is an example of a system-in-package in which connection among three semiconductor chips 3D, 3H and 3L including a source pad 7 of the semiconductor chip 3H in which a high-side MOSFET is formed, and a source pad 7 of the semiconductor chip 3L in which a low-side MOSFET is formed, is carried out only by Au wires 11.

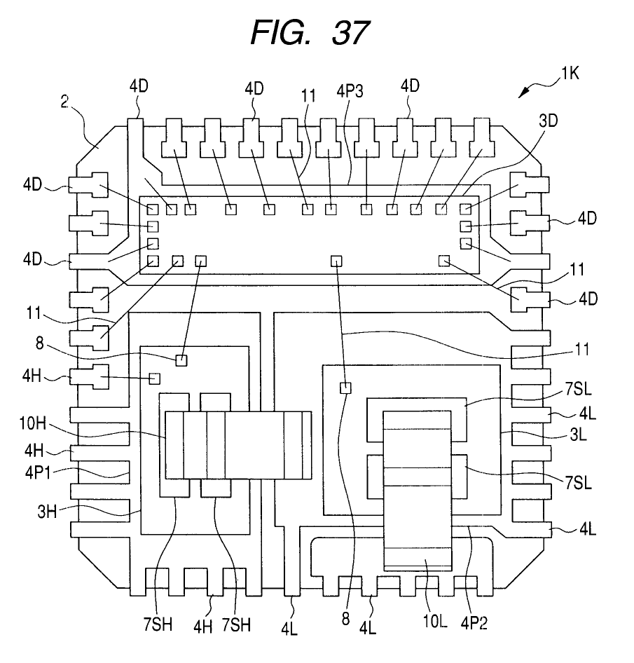

On the other hand, a semiconductor device 1K shown in FIG. 37 is an example of a system-in-package in which source pads 7SH of a semiconductor chip 3H and source pads 7SL of a semiconductor chip 3L are coupled to Al ribbons 10H and 10L, respectively. Element sizes of a high-side MOSFET formed in the semiconductor chip 3H and a low-side MOSFET formed in the semiconductor chip 3L are the same as those of the semiconductor device 1J shown in FIG. 36, respectively.

As is clear from comparison between FIGS. 36 and 37, even if the element sizes of the high-side MOSFET and the low-side MOSFET are the same sizes, respectively, when the source pads 7SH of the semiconductor chip 3H and the source pads 7SL of the semiconductor chip 3L are coupled to the Al ribbons 10H and 10L, respectively, the sizes of the semiconductor chips 3H and 3L can be reduced. This is because when the source pads 7SH and 7SL are coupled to the Al ribbons 10H and 10L, respectively, contact areas between them are larger than that when the source pads 7SH and 7SL are coupled to the Au wires 11, respectively, resulting in reduced on-resistance of a Power MOSFET, and, if the Power MOSFET has the same on-resistance, since areas of the source pads 7SH and 7SL can be reduced, the sizes of the semiconductor chips 3H and 3L can be reduced accordingly.

If the sizes of the semiconductor chips 3H and 3L are reduced, as shown in FIG. 37, a size of a die pad portion 4P3 for mounting a semiconductor chip 3D contained in a same size resin package, can be increased. Accordingly, a size of the semiconductor chip 3D mounted over the die pad portion 4P3 can be increased, and a number of pads formed in the semiconductor chip 3D can be increased, enabling the semiconductor device 1K to have more functions than those of the semiconductor device 1J.

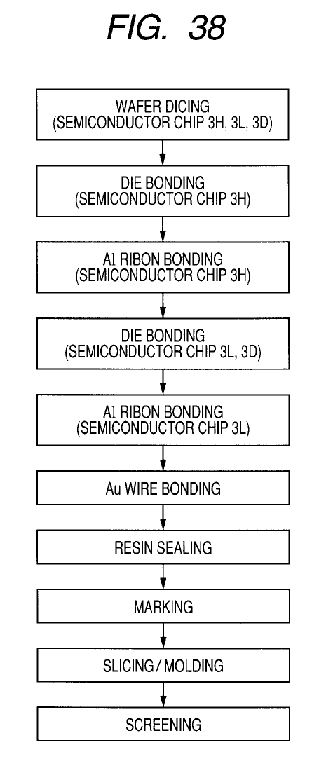

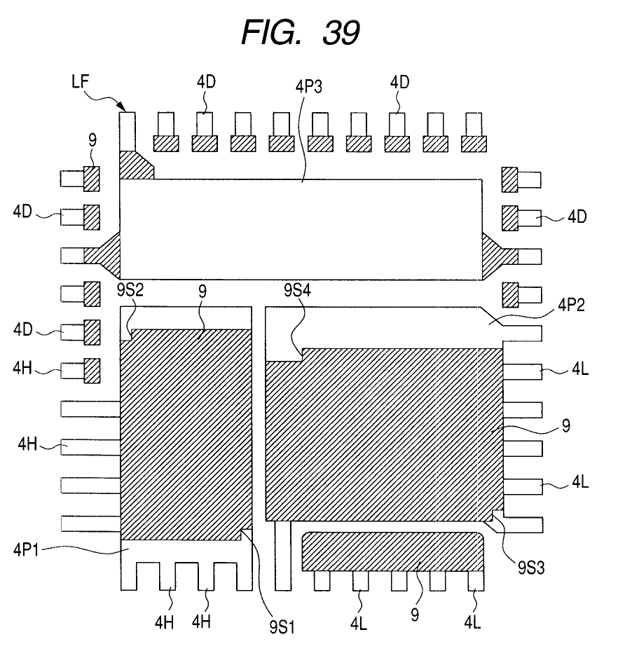

Next, with reference to FIG. 38 (an entire flow diagram) and FIGS. 39 to 46 (plan views of each of steps), an example of a manufacturing process of the semiconductor device 1K will be described.

First, according to a usual manufacturing method, semiconductor chips 3H, 3L and 3D are obtained, by dicing three types of silicon wafers over which high-side MOSFETs, low-side MOSFETs, and driver IC circuits (or control IC circuits) are formed, respectively.

Next, as shown in FIG. 39, a lead frame LF where a plurality of leads 4D, 4H and 4L, and die pad portions 4P1, 4P2 and 4P3 are formed is prepared. The lead frame LF is made of Cu alloy or Fe—Ni alloy, and in a part (a hatched area in the figure) of a surface thereof, for example, a plated layer 9 mainly composed of a Pd film as described in the first embodiment is formed. Moreover, in the lead frame LF, notched portions 9S1 to 9S4 are provided at the plated layers 9 of the die pad portions 4P1 and 4P2. The effect of providing the notched portions 9S1 to 9S4 at the plated layers 9 of the die pad portions 4P1 and 4P2 will be described later.

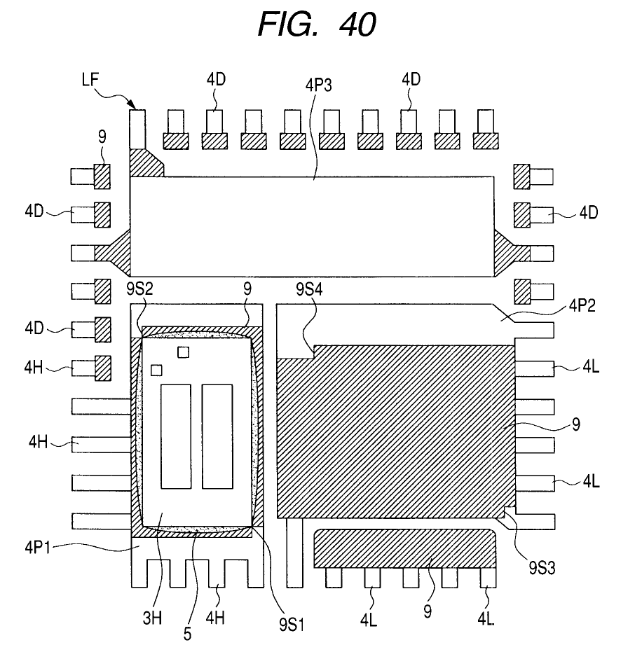

Next, as shown in FIG. 40, the semiconductor chip 3H is die-bonded onto the die pad portion 4P1 using an Ag paste 5. The Ag paste 5 having the same composition as that of the Ag paste described in the first embodiment is used.

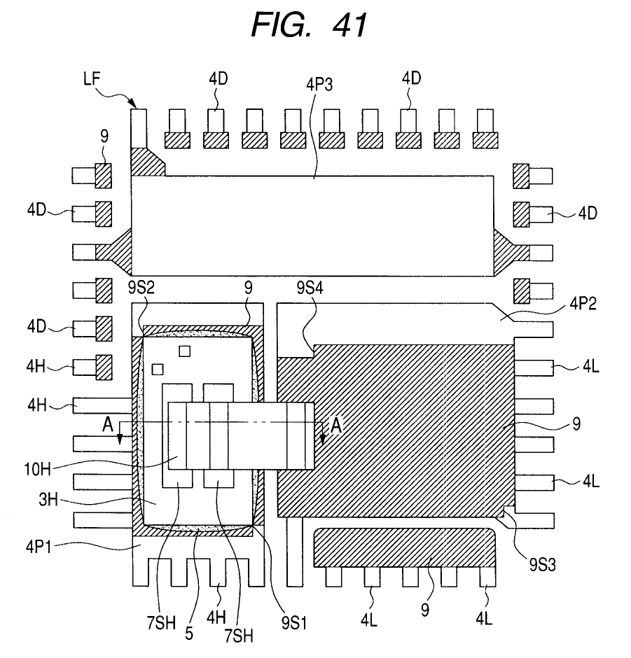

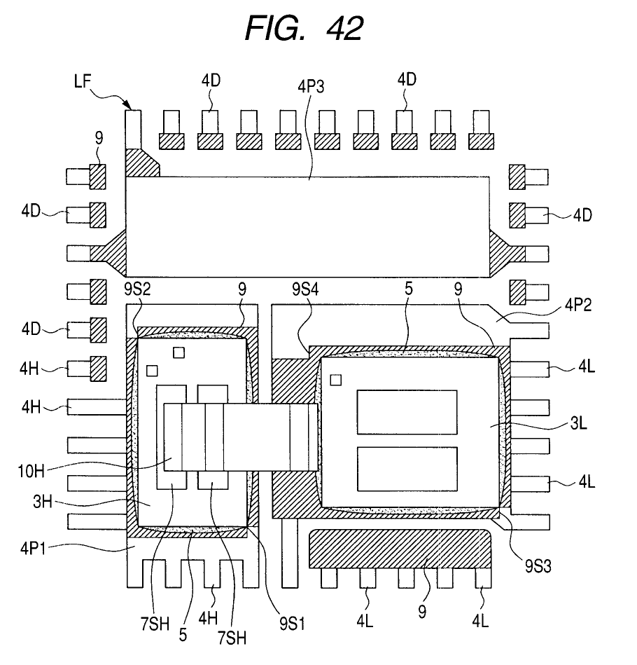

Next, as shown in FIG. 41, source pads 7SH of the semiconductor chip 3H and die pad portion 4P2 are electrically coupled each other by an Al ribbon 10H by a wedge bonding process utilizing ultrasonic waves. In addition, if after the semiconductor chips 3H and 3L are die-bonded onto the die pad portions 4P1 and 4P2 by the Ag paste 5, respectively, the source pads 7SH of the semiconductor chip 3H and the die pad portion 4P2 are electrically coupled each other by the Al ribbon 10H, as shown FIG. 42, in some times the Ag paste 5 spreading outside of the semiconductor chip 3L and the Al ribbon 10H will interfere each other, and the Al ribbon 10H and die pad portion 4P2 can not be normally coupled each other. Accordingly, it is desirable to couple the source pads 7SH of the semiconductor chip 3H and the die pad portion 4P2 each other by the Al ribbon 10H before die-bonding the semiconductor chip 3L onto the die pad portion 4P2. However, if the semiconductor chips 3H and 3L are die-bonded onto the die pad portions 4P1 and 4P2, respectively, and after that, the source pads 7SH of the semiconductor chip 3H and the die pad portion 4P2 are electrically coupled each other by the Al ribbon 10H, since the Ag paste 5 applied on the die pad portion 4P1 and the Ag paste 5 applied on the die pad portion 4P2 can be cured simultaneously by one time of baking processing, efficiency of a die-bonding operation will be improved.

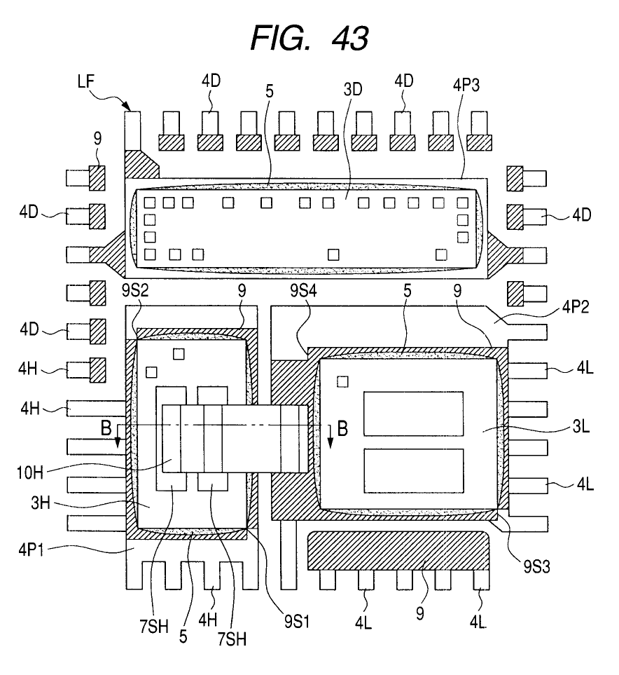

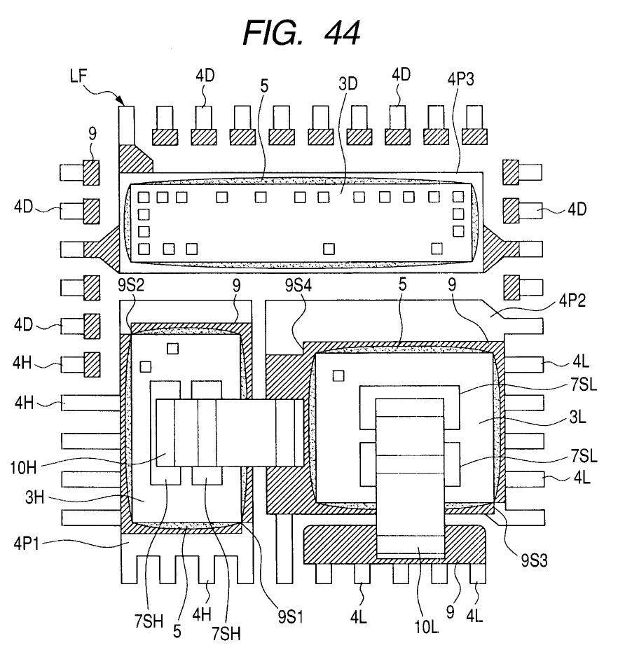

Next, as shown in FIG. 43, semiconductor chips 3L and 3D are die-bonded onto the die pad portions 4P2 and 4P3 using the Ag paste 5, respectively, and after that, as shown in FIG. 44, by a wedge bonding process utilizing ultrasonic waves, the source pads 7SL of the semiconductor chip 3L and the leads 4L are electrically coupled by an Al ribbon 10L. In addition, since the semiconductor chip 3D in which a driver IC circuit (or a control IC circuit) is formed has no drain electrode on a rear surface thereof, it may be die-bonded onto the die pad portion 4P3 using an adhesive except for the Ag paste 5 having the above-mentioned composition.

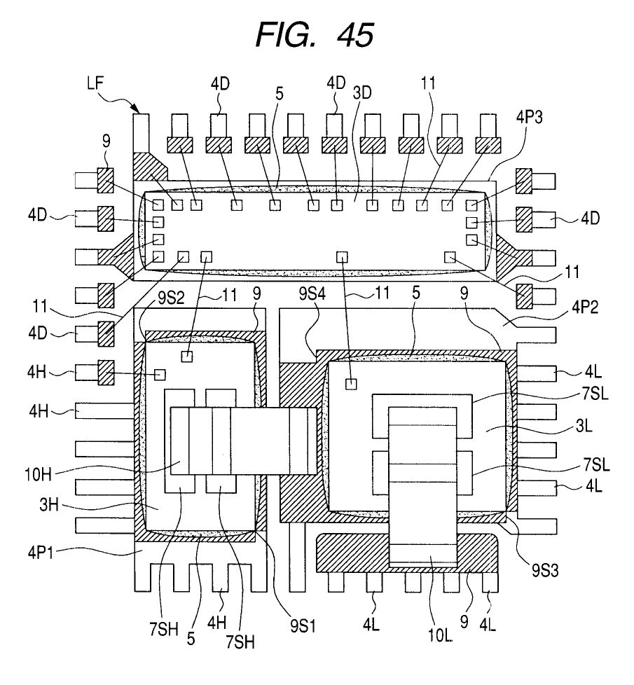

Next, as shown in FIG. 45, by a ball bonding process utilizing heat and ultrasonic waves, between the semiconductor chip 3D and the semiconductor chips 3H and 3L, and between the semiconductor chip 3D and the leads 4D are electrically coupled each other by an Au wire 11, respectively.

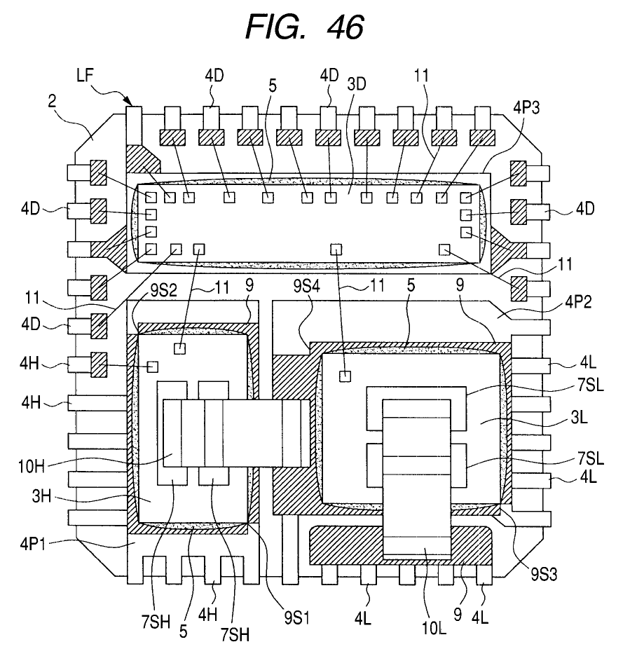

Next, as shown in FIG. 46, the semiconductor chips 3H, 3L and 3D (including the die pad portions 4P1 to 4P3, the Al ribbons 10H and 10L, the Au wires 11, and the inner lead portions of the leads 4H, 4L and 4D) are sealed with a molding resin 2. Then, although not shown in the figure, the product name, the production number, and the like are marked on the surface of the molding resin 2. Subsequently, unnecessary portions of the leads 4H, 4L and 4D exposed outside the molding resin 2 are cut and removed, then, the outer lead portions of the leads 4H, 4L and 4D are formed in a predetermined shape, and finally, a product is passed through a screening step of determining whether the product is acceptable or not, resulting in completion of the semiconductor device 1K.

Among the above-mentioned manufacturing steps of the semiconductor device 1K, in the step of die-bonding the semiconductor chip 3H onto the die pad portion 4P1 (FIG. 40), it is necessary to align the die pad portion 4P1 and the semiconductor chip 3H suitably.

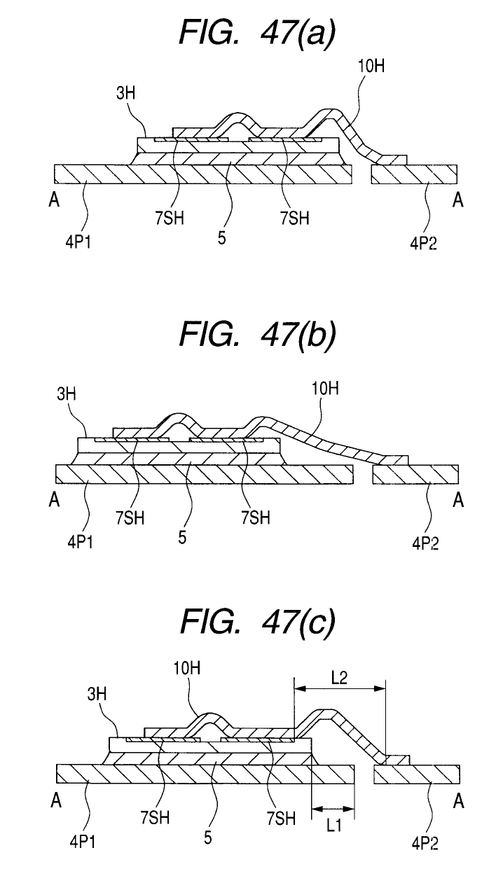

For example, as shown in FIG. 47(a) (a section view along an A-A line of FIG. 41), when die-bonding the semiconductor chip 3H onto the die pad portion 4P1, if the semiconductor chip 3H approaches to the neighboring die pad portion 4P2 too much, a distance along which the source pads 7SH of the semiconductor chip 3H and the die pad portion 4P2 are coupled each other will be too short. As a result, strong bending stress is imparted on a portion of the Al ribbon 10H between the source pads 7SH and the die pad portion 4P2, causing bonding defects such as breakage and abnormal loop of the Al ribbon 10H to occur easily.

On the contrary, as shown in FIG. 47(b), when die-bonding the semiconductor chip 3H onto the die pad portion 4P1, if the semiconductor chip 3H is apart from the neighboring die pad portion 4P2 too much, the distance along which the source pads 7SH of the semiconductor chip 3H and the die pad portion 4P2 are coupled each other will be too long, resulting in causing shortage defects that are contact between the Al ribbon 10H and an end portion of the silicon chip 3H and an end portion of the die pad portion 4P1 to occur easily.

As mentioned above, in the plated layers 9 of the die pad portions 4P1 and 4P2 over which the semiconductor chips 3H and 3L are mounted, respectively, notched portions 9S1 to 9S4 are provided. Accordingly, in the present embodiment, when mounting the semiconductor chip 3H over the die pad portion 4P1 (refer to FIG. 40), the semiconductor chip 3H is aligned with respect to the notched portion 9S1 provided to the plated layer 9 of the die pad portion 4P1. As shown in FIG. 47(c), this enables to optimize the distance (L1) from an end portion of the semiconductor chip 3H to an end portion of the die pad portion 4P1. Accordingly, a distance (L2) from the source pad 7SH of the semiconductor chip 3H to a bonging region of the die pad portion 4P2 is also optimized, enabling good bonding to be achieved. Moreover, the notched portion 9S2 provided to a position diagonally facing the notched portion 9S1, can be used to detect displacement of the semiconductor chip 3H if it is rotated with respect to the die pad portion 4P1.

Similarly, in the step of die-bonding the semiconductor chip 3L onto the die pad portion 4P2 (FIG. 43), it is necessary to align the die pad portion 4P2 and the semiconductor chip 3L suitably.

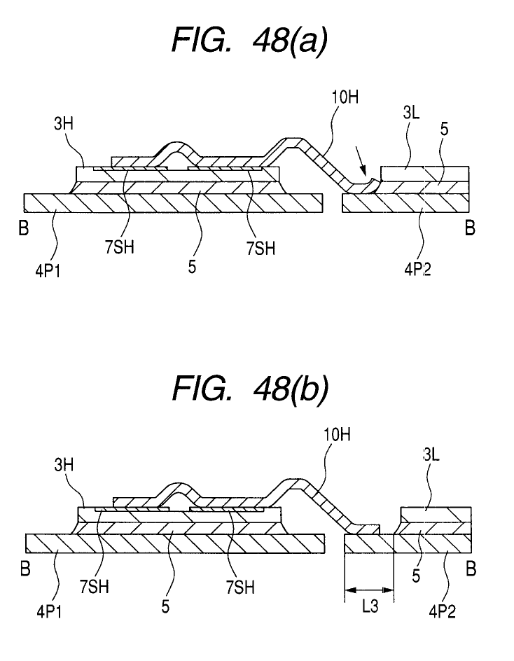

For example, as shown in FIG. 48(a) (a section view along a B-B line in FIG. 43), when die-bonding the semiconductor chips 3H and 3L onto the die pad portions 4P1 and 4P2 using the Ag paste 5, respectively, if the semiconductor chip 3L approaches to the neighboring die pad portion 4P1 too much, an area of the bonding region of the die pad portion 4P2 will be small. As a result, when bonding one end of the Al ribbon 10H onto the die pad portion 4P2, since problems such as in that a wedge of a bonding machine cannot contact the region, and in that a contact area between the wedge and the Al ribbon 10H becomes small will occur, it will be difficult to perform good bonding of the Al ribbon 10H onto the die pad portion 4P2.

Thus, in the present embodiment, when mounting the semiconductor chip 3L over the die pad portion 4P2 (refer to FIG. 43), the semiconductor chip 3L is aligned with respect to the notched portion 9S3 provided to the plated layer 9 of the die pad portion 4P2. As shown in FIG. 48(b), since this enables to optimize a distance (L3) from an end portion of the semiconductor chip 3H (Ag paste 5) to an end portion of the die pad portion 4P2, the area of the bonding region of the die pad portion 4P2 can be ensured, enabling good bonding of the Al ribbon 10H onto the die pad portion 4P2 to be achieved. Moreover, since aligning the semiconductor chip 3H with respect to the notched portion 9S3 enables to optimize a distance between the semiconductor chip 3L and the leads 4L, good bonding of the die pad portion 4P2 with respect to the leads 4L is enabled (in this point, description is the same as that of FIG. 47). Moreover, in the same manner as the notched portion 9S2, the other notched portion 9S4 provided to a position diagonally facing the notched portion 9S3 can be used to detect displacement of the semiconductor chip 3L if it is rotated with respect to the die pad portion 4P2. Furthermore, the notched portion 9S4 can also be used to confirm the range of the bonding region of the Al ribbon 4H.

The notched portions 9S1 to 9S4 are applicable not only to the semiconductor device of the present embodiment 10 but also to the semiconductor devices of the embodiments 1 to 9. Moreover, although, in the present embodiment, the die pad portion 4P1 is provided with two notched portions 9S1 and 9S2 and the die pad portion 4P2 is provided with two notched portions 9S3 and 9S4, it is sufficient for the die pad portions 4P1 and 4P2 to be provided with one 9S1 and one 9S3, respectively, thereby, they may not have 9S2 or 9S4.

As shown in FIG. 39, in the lead frame LF of the present embodiment, a plated layer 9 is formed on the die pad portion 4P1 over which the semiconductor chip 3H having a high-side MOSFET formed therein is mounted, and on the die pad portion 4P2 over which the semiconductor chip 3L having a low-side MOSFET formed therein is mounted, but it is not formed on the die pad portion 4P3 over which the semiconductor chip 3D is mounted.

On each of the high-side MOSFET and the low-side MOSFET, a rear surface electrode (a drain electrode) is formed. They are electrically coupled to the die pad portions 4P1 and 4P2, respectively. By forming the plated layer 9 on each of the die pad portions 4P1 and 4P2 so as to prevent the die pad portions 4P1 and 4P2 mainly composed of copper from being oxidized, parasitic resistance of each of the drains is reduced.

On the contrary, the reason for not forming the plated layer 9 on the die pad portion 4P3 over which the semiconductor chip 3D having a driver IC (or a control IC) formed therein is that the driver IC or the control IC has no rear surface electrode formed, thereby it is not necessary for the rear surface thereof to be electrically coupled to the die pad portion 4P3. The further reason thereof is that bonding strength between the molding resin 2 and the die pad portion 4P3 can be improved.

The invention made by the present inventor has been so far explained in reference to preferred embodiments thereof. However, the invention is not limited thereto and it is obvious that these details may be modified in various ways without departing from the spirit and scope of the invention.

The element formed in a semiconductor chip is not limited to a power MOSFET, instead, it may be an element such as an IGBT (Insulated Gate Bipolar Transistor). Moreover, instead of an Al ribbon, such a ribbon may also be used that is constituted with a metal material having low electric resistance, such as Au or a Cu alloy.

The present invention may be applied to a power semiconductor device used for a power control switch and a charge/discharge protection circuit switch etc. of a portable information apparatus.

What is claimed is:

1. A semiconductor device in which a first semiconductor chip mounted over a first die pad portion and a second semiconductor chip mounted over a second die pad portion are sealed in a resin package, and outer lead portions of a plurality of leads are exposed from a side surface of the resin package;
wherein on a main surface of each of the first and second semiconductor chips, there are formed a power MOSFET, a gate pad coupled to a gate electrode of the power MOSFET, and a source pad coupled to a source of the power MOSFET and having an area larger than that of the gate pad;
wherein on a rear surface of each of the first and second semiconductor chips, a drain electrode of the power MOSFET is formed;
wherein between the rear surface of the first semiconductor chip and the first die pad portion, and between the rear surface of the second semiconductor chip and the second die pad portion, Ag pastes are intervened, respectively;
wherein the leads include a first gate lead electrically coupled to the gate pad of the first semiconductor chip, a first source lead electrically coupled to the source pad of the first semiconductor chip, a second gate lead electrically coupled to the gate pad of the second semiconductor chip, and a second source lead electrically coupled to the source pad of the second semiconductor chip; and
wherein at least the source pad of the first semiconductor chip and the first source lead are electrically coupled each other by a metal ribbon.

2. The semiconductor device according to claim 1,
wherein the source pad of the second semiconductor chip and the second source lead are electrically coupled each other by a metal wire.

3. The semiconductor device according to claim 1,
wherein an elastic modulus of the Ag paste is within a range of 0.2 to 5.3 GPa, and a shearing strength thereof is 8.5 MPa or more.

4. The semiconductor device according to claim 1,
wherein the first gate lead and the second source lead are exposed from a first side surface of the resin package, and the second gate lead and the second source lead are exposed from a second side surface of the resin package.

5. The semiconductor device according to claim 1,
wherein on a surface of each of the first and second die pad portions, the first and second gate leads, and the first and second source leads, a plated layer containing Pd as a principal component is formed.

6. The semiconductor device according to claim 1,
wherein a rear surface of each of the first and second die pad portions is exposed from the resin package.

7. The semiconductor device according to claim 1,
wherein a DC-DC converter is constituted by a power MOSFET formed over the main surface of the first semiconductor chip and a power MOSFET formed on the main surface of the second semiconductor chip.

8. The semiconductor device according to claim 1,
wherein a part of the first die pad portion is integrally formed with a first drain lead extending near the second die pad portion, and the source pad of the second semiconductor chip and the first drain lead are electrically coupled each other by a metal wire or a metal ribbon.

9. The semiconductor device according to claim 8,
wherein inside the resin package, the first drain lead is bent-formed so as to separate from a bottom surface of the resin package.

10. The semiconductor device according to claim 1,
wherein the source pad of the first semiconductor chip and the first source lead are electrically coupled each other by a plurality of the metal ribbons.

11. A semiconductor device in which a semiconductor chip mounted on a die pad portion is sealed in a resin package, and outer lead portions of a plurality of leads are exposed from a side surface of the resin package;
wherein on a main surface of the semiconductor chip, there are formed a power MOSFET, a gate pad coupled to a gate electrode of the power MOSFET, and a plurality of source pads coupled to a source of the power MOSFET and having an area larger than that of the gate pad;
wherein on a rear surface of the semiconductor chip, a drain electrode of the power MOSFET is formed;
wherein between the rear surface of semiconductor chip and the die pad portion, an Ag paste is intervened;
wherein the leads include a gate lead electrically coupled to the gate pad of semiconductor chip and a source lead electrically coupled to the source pad of semiconductor chip;
wherein, each of the source pads and the source lead are electrically coupled each other by a metal ribbon; and
wherein, the gate pad is arranged among the source pads.

12. The semiconductor device according to claim 11,
wherein the gate pad and the gate lead are electrically coupled each other by a metal wire.

13. The semiconductor device according to claim 11,
wherein an elastic modulus of the Ag paste is within a range of 0.2 to 5.3 GPa, and a shearing strength thereof is 8.5 MPa or more.

14. The semiconductor device according to claim 11,
wherein the gate lead and the source lead are exposed from a first side surface of the resin package, and a drain lead integrally formed with the die pad portion is exposed from a second side surface of the resin package.

15. The semiconductor device according to claim 11,
wherein on a surface of each of the die pad portion, the gate lead and the source lead, a plated layer containing Pd as a principal component is formed.

16. The semiconductor device according to claim 15,
wherein in a part of the plated layer formed on the surface of the die pad portion, notched portions for aligning the semiconductor chip when mounting it over the die pad portion are provided.

17. The semiconductor device according to claim 15,
wherein in a part of the plated layer formed on the surface of the die pad portion, notched portions for aligning the metal ribbon when bonding it onto the die pad portion are provided.
